(19) United States
(12) Patent Application Publication
(10) Pub. No.: US 2026/0013213 A1
(43) Pub. Date: Jan. 8, 2026

(54) SEMICONDUCTOR DEVICE

(71) Applicant: SAMSUNG ELECTRONICS CO., LTD., Suwon-si (KR)

(72) Inventors: Dahye KIM, Suwon-si (KR); Juhun PARK, Suwon-si (KR); Cheoljin YUN, Suwon-si (KR); Daihong HUH, Suwon-si (KR)

(21) Appl. No.: 19/001,231

(22) Filed: Dec. 24, 2024

(30) Foreign Application Priority Data
Jul. 5, 2024 (KR) 10-2024-0089083

(51) Int. Cl. H10D 84/83; H10D 30/00; H10D 30/01; H10D 30/43; H10D 62/10; H10D 62/13; H10D 64/01; H10D 64/23; H10D 84/01

(52) U.S. Cl. CPC H10D 84/8312; H10D 30/014; H10D 30/0191; H10D 30/43; H10D 30/501; H10D 62/121; H10D 62/151; H10D 64/017; H10D 64/251; H10D 84/013; H10D 84/0149; H10D 84/832

(57) ABSTRACT

A semiconductor device includes a first active pattern including first sheets spaced apart in a first direction perpendicular to a surface of a substrate, a second active pattern on the first active pattern and including second sheets spaced apart in the first direction, a first source/drain pattern connected to the first active pattern in a second direction, a second source/drain pattern on the first source/drain pattern and connected to the second active pattern in the second direction, and a gate electrode extending in a third direction and extending around the first and the second active patterns. The first source/drain pattern includes a first film along an inner surface of a recess where the first source/drain pattern is disposed and a second film on the first film and filling the recess. On a cross-section including the first and third directions, the recess decreases in width with decreasing distance to the substrate.

### CROSS-REFERENCE TO RELATED APPLICATION(S)

This application claims the benefit of priority under 35 U.S.C. § 119 to Korean Patent Application No. 10-2024-0089083, filed on Jul. 5, 2024, in the Korean Intellectual Property Office, the disclosure of which is incorporated herein by reference in its entirety.

### BACKGROUND

Example embodiments relate generally to a semiconductor device.

As one of the scaling technologies for raising the density of an integrated circuit device, a multi-gate transistor has been suggested, in which a fin-shaped or nanowire-shaped silicon body is formed on a substrate and gates are formed on a surface of the silicon body.

Meanwhile, as the scaling of the multi-gate transistor shrinks, a three-dimensional stacked semiconductor device in which a lower nanosheet transistor and an upper nanosheet transistor are stacked is introduced

### SUMMARY

An aspect provides a semiconductor device whose degree of integration is improved.

Another aspect also provides a semiconductor device whose channel strain control ability is improved.

Another aspect also provides a semiconductor device whose electrical reliability is improved.

Example embodiments are not limited to the technical features described above, and other unstated technical features may be made apparent to those skilled in the art from the following description.

According to an aspect, there is provided a semiconductor device including a first active pattern that includes a plurality of first sheets spaced apart in a first direction perpendicular to a surface of a substrate, a second active pattern on the first active pattern and including a plurality of second sheets spaced apart in the first direction, a first source/drain pattern connected to the first active pattern in a second direction intersecting the first direction, a second source/drain pattern on the first source/drain pattern and connected to the second active pattern in the second direction, and a gate electrode extending in a third direction intersecting the first direction and the second direction and surrounding (i.e., extending around) the first active pattern and the second active pattern, and the first source/drain pattern may include a first film formed along an inner surface of a recess where the first source/drain pattern is disposed and a second film on the first film and filling the recess, and, on a cross-section including the first direction and the third direction, the recess may decrease in width as it extends closer to the substrate.

According to another aspect, there is also provided a semiconductor device including a first active pattern that includes a plurality of first sheets spaced apart in a first direction perpendicular to a surface of a substrate, a second active pattern on the first active pattern and including a plurality of second sheets spaced apart in the first direction, a first source/drain pattern connected to the first active pattern in a second direction intersecting the first direction, a second source/drain pattern on the first source/drain pattern and connected to the second active pattern in the second direction, a gate electrode extending in a third direction intersecting the first direction and the second direction and surrounding the first active pattern and the second active pattern, a first fence film on a sidewall of the first source/drain pattern in the third direction, and a second fence film on the first fence film in the third direction.

According to another aspect, there is also provided a semiconductor device including a first active pattern that includes a plurality of first sheets spaced apart in a first direction perpendicular to a surface of a substrate, a second active pattern on the first active pattern and including a plurality of second sheets spaced apart in the first direction, a first source/drain pattern connected to the first active pattern in a second direction intersecting the first direction, a second source/drain pattern on the first source/drain pattern and connected to the second active pattern in the second direction, a fin-type pattern protruding from the substrate in the first direction, extending in the second direction, and disposed below the first active pattern, a gate electrode extending in a third direction intersecting the first direction and the second direction and surrounding the first active pattern and the second active pattern, a first fence film on a sidewall of the first source/drain pattern in the third direction, and a second fence film on the first fence film in the third direction, and the fin-type pattern may include a protrusion part disposed between the first source/drain pattern and the first fence film in the third direction, and the first source/drain pattern may include a first film formed along an inner surface of a recess where the first source/drain pattern is disposed and a second film on the first film and filling the recess, and the first source/drain pattern may have a p-type, and the second source/drain pattern may have an n-type.

Additional aspects of example embodiments will be set forth in part in the description which follows and, in part, will be apparent from the description, or may be learned by practice of the disclosure.

According to example embodiments of the present disclosure, it is possible to improve a degree of integration of a semiconductor device.

According to example embodiments of the present disclosure, it is possible to improve a channel strain control ability of a semiconductor device.

According to example embodiments of the present disclosure, it is possible to improve electrical reliability of a semiconductor device.

### BRIEF DESCRIPTION OF THE DRAWINGS

These and/or other aspects, features, and advantages of the invention will become apparent and more readily appreciated from the following description of example embodiments, taken in conjunction with the accompanying drawings, wherein like reference numerals (when used) indicate corresponding elements throughout the several views, and in which:

FIG. 1 is a diagram showing a schematic layout of a semiconductor device according to some example embodiments;

FIG. 2 is a schematic diagram for illustrating a cross-section taken along line A-A of FIG. 1;

FIG. 3 is a schematic diagram for illustrating a cross-section taken along line B-B of FIG. 1;

FIG. 4 is an enlarged view showing region P of FIG. 3;

FIG. 5 is a schematic diagram for illustrating a cross-section taken along line C-C of FIG. 1;

FIG. 6 is a schematic cross-sectional view taken along line A-A of FIG. 1 for illustrating a semiconductor device according to some other example embodiments;

FIG. 7 is a schematic cross-sectional view taken along line C-C of FIG. 1 for illustrating a semiconductor device according to some other example embodiments;

FIG. 8 is a schematic cross-sectional view taken along line A-A of FIG. 1 for illustrating a semiconductor device according to still other example embodiments;

FIG. 9 is a schematic cross-sectional view taken along line B-B of FIG. 1 for illustrating a semiconductor device according to still other example embodiments;

FIG. 10 is a schematic cross-sectional view taken along line B-B of FIG. 1 for illustrating a semiconductor device according to still other example embodiments;

FIG. 11 is a schematic cross-sectional view taken along line B-B of FIG. 1 for illustrating a semiconductor device according to still other example embodiments;

FIG. 12 is a schematic cross-sectional view taken along line B-B of FIG. 1 for illustrating a semiconductor device according to still other example embodiments;

FIG. 13 is a schematic cross-sectional view taken along line B-B of FIG. 1 for illustrating a semiconductor device according to still other example embodiments;

FIG. 14 is a schematic cross-sectional view taken along line B-B of FIG. 1 for illustrating a semiconductor device according to still other example embodiments;

FIG. 15 is a schematic cross-sectional view taken along line A-A of FIG. 1 for illustrating a semiconductor device according to still other example embodiments;

FIG. 16 is a schematic cross-sectional view taken along line B-B of FIG. 1 for illustrating a semiconductor device according to still other example embodiments; and

FIGS. 17 to 42 are schematic cross-sectional views depicting intermediate stages for illustrating a manufacturing method of a semiconductor device according to some example embodiments.

### DETAILED DESCRIPTION

Before describing example embodiments in detail, the words and terminologies used in the specification and claims are not to be construed as limited to common or dictionary meanings but construed as meanings and conceptions coinciding with the technical spirit of the present disclosure under a principle that the inventor(s) may appropriately define the conception of the terminologies to explain the invention in the optimum manner. Therefore, the example embodiments described in the specification and the configurations illustrated in the drawings are no more than the most preferred example embodiments of the present disclosure and do not fully cover the spirit of the present disclosure. Accordingly, it should be understood that there may be various equivalents and modifications that may replace those when this application is filed.

In the descriptions below, a singular expression may include a plural expression as well unless apparently otherwise defined by context. In the present disclosure, it should be understood that terms such as “comprise” or “include” and “consist of” are intended to indicate the presence of a feature, a number, a step, an operation, an element, a component, or a combination thereof which are described in the specification and not intended to previously exclude the possibility of the presence or addition of one or more other features, numbers, steps, operations, elements, components, or combinations thereof.

In addition, expressions such as upper side, upper portion or above, lower side, lower portion or below, side surface, front surface, and back surface hereinafter are represented based on a direction illustrated in a drawing and may be represented otherwise when the direction of a corresponding object changes. The shape and/or size of elements shown in the drawings may be exaggerated for clearer description.

The drawings regarding a semiconductor device according to some example embodiments illustrate a fin field-effect transistor (FinFET) including a channel region in a fin-type pattern shape, a transistor including nanowire or nanosheet, and a multi-bridge channel field effect transistor (MBCFET) for example, but embodiments are not limited thereto.

The semiconductor device according to some example embodiments may include a tunneling FET, a three-dimensional (3D) transistor, or a vertical FET. The semiconductor device according to some example embodiments may also include a planar transistor. In addition, the present disclosure may be applied to 2D material-based FETs and a heterostructure thereof. Further, the semiconductor device according to some example embodiments may also include a bipolar junction transistor and a lateral double-diffused metal-oxide-semiconductor (LDMOS) transistor.

Hereinafter, example embodiments of the present disclosure will be described with reference to the accompanying drawings.

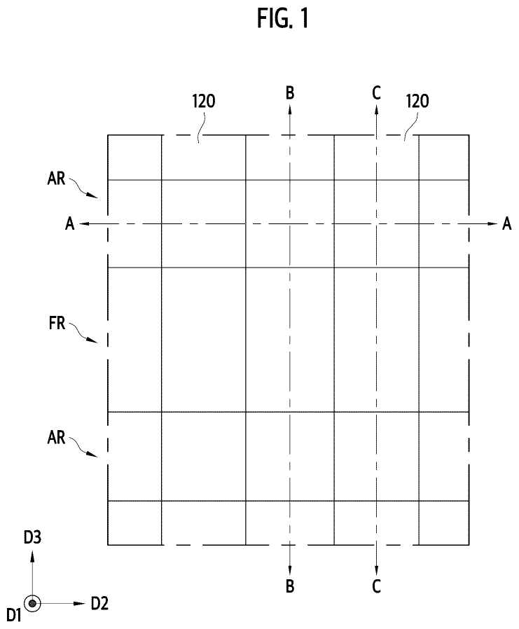

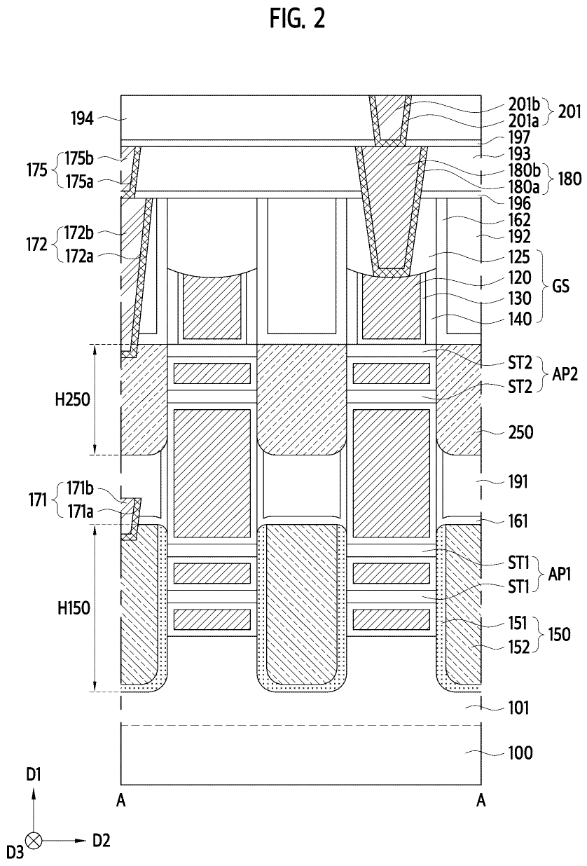

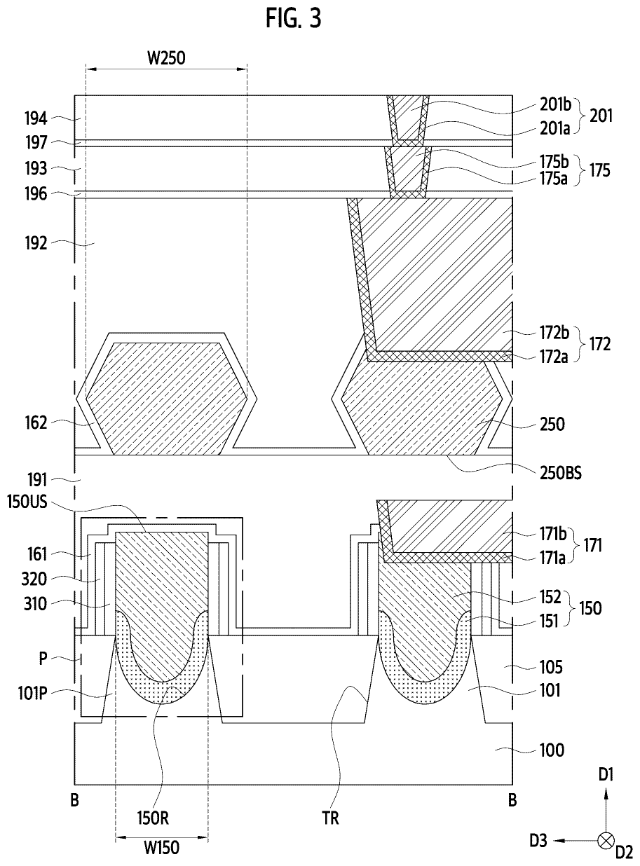

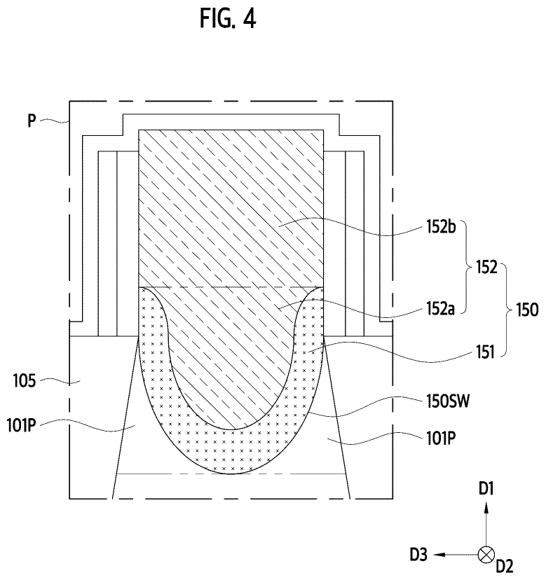

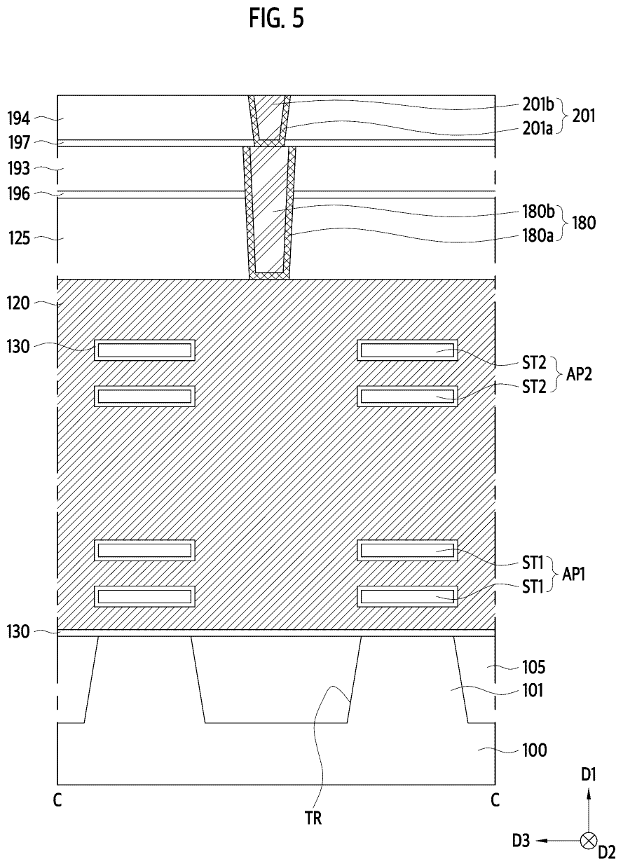

FIG. 1 is a schematic plan view depicting a layout of a semiconductor device according to some example embodiments. FIG. 2 is a schematic diagram for illustrating a cross-section taken along line A-A of FIG. 1, and FIG. 3 is a schematic diagram for illustrating a cross-section taken along line B-B of FIG. 1. FIG. 4 is an enlarged view showing region P of FIG. 3, and FIG. 5 is a schematic diagram for illustrating a cross-section taken along line C-C of FIG. 1.

Referring to FIGS. 1 to 5, a semiconductor device according to some example embodiments may include a substrate 100, a fin-type pattern 101, a first active pattern AP1, a second active pattern AP2, a gate structure GS, a first source/drain pattern 150, a second source/drain pattern 250, a first fence film 310, and a second fence film 320.

According to some example embodiments, the substrate 100 may include an active region AR and a field region FR. The active region AR and the field region FR may extend in a second direction D2. The active region AR and the field region FR may be disposed to alternate each other in a third direction D3. For example, the active region AR may be disposed between adjacent field regions FR in the third direction D3. The field region FR may be disposed between adjacent active regions AR in the third direction D3. In this case, each of the second direction D2 and the third direction D3 may indicate a direction being parallel to a surface (upper or lower surface) of the substrate 100 and intersecting a first direction D1. The first direction D1 may indicate a direction perpendicular to the surface of the substrate 100. The second direction D2 may indicate a direction in which the active region AR and the field region FR extend. The third direction D3 may indicate a direction in which the active region AR and the field region FR are disposed alternately.

According to some example embodiments, the field region FR may be defined by a trench TR but is not limited thereto. In addition, it is apparent that those of ordinary skill in the art to which the present disclosure pertains may sort each portion into a field region and an active region. The field region FR may have a shallow trench isolation (STI) structure. However, example embodiments are not limited thereto. For example, the field region FR may also be defined by a deep trench.

According to some example embodiments, an element isolation film may be disposed around the active regions AR spaced from each other. In this case, a portion located between two adjacent active regions AR in the element isolation film may be the field region FR. For example, a portion in which a channel region of a transistor, which may be one example of the semiconductor device, is formed may be an active region, and a portion for dividing the channel region of the transistor, which is formed in the active region, may be a field region. Alternatively, the active region may be a portion where a fin-type pattern used as the channel region of the transistor or a nanosheet is formed, and the field region may be a portion where a fin-type pattern used as the channel region or a nanosheet is not formed.

According to some example embodiments, the substrate 100 may be bulk silicon or silicon-on-insulator (SOI). Instead, the substrate 100 may be a silicon substrate or may include, but is not limited to, other materials such as silicon germanium, silicon germanium on insulator (SGOI), indium antimonide, lead telluride, indium arsenide, indium phosphide, gallium arsenide, and gallium antimonide.

According to some example embodiments, the fin-type pattern 101 may be disposed on the active region AR of the substrate 100. The fin-type pattern 101 may protrude (i.e., extend) from the substrate 100. The fin-type pattern 101 may extend longitudinally in the second direction D2. The fin-type pattern 101 may be formed by etching a portion of the substrate 100 or may include an epitaxial layer grown from the substrate 100. The fin-type pattern 101 may include silicon or germanium, which is an elemental semiconductor material.

According to some example embodiments, the fin-type pattern 101 may include a protrusion part 101P. The protrusion part 101P may be disposed between the first source/drain pattern 150 and a field insulating film 105 in the third direction D3. In other words, the protrusion part 101P may be disposed on a sidewall 150SW of the first source/drain pattern disposed in the third direction D3. The protrusion part 101P may cover the sidewall 150SW of the first source/drain pattern in the third direction D3. The term “cover” (or “covers,” or like terms), as may be used herein, is intended to broadly refer to an element, structure or layer that is on or over another element, structure or layer, either directly or with one or more other intervening elements, structures or layers therebetween. The first source/drain pattern 150 may overlap the protrusion part 101P in the third direction D3. As used herein, “an element A overlapping an element B in a direction X” (or similar language) means that there is at least one line that extends in the direction X and intersects both the elements A and B.

According to some example embodiments, the protrusion part 101P may decrease in width in the third direction D3 as the protrusion part 101P extends farther from the substrate 100 in the first direction D1. For example, the protrusion part 101P may have an upwardly pointed shape. The protrusion part 101P may be disposed between the sidewall 150SW of the first source/drain pattern and the field insulating film 105 in the third direction D3.

According to some example embodiments, the fin-type pattern 101 may include silicon (Si). For another example, the fin-type pattern 101 may include a compound semiconductor and may include, for example, IV-IV compound semiconductor or III-V compound semiconductor. The IV-IV compound semiconductor may be a binary compound, for example, including at least two or more of carbon (C), silicon (Si), germanium (Ge), and tin (Sn), a ternary compound, or a compound doped with a group IV element thereto. The III-V compound semiconductor may be one of a binary compound formed, for example, as at least one of aluminum (Al), gallium (Ga), and indium (In) that are group III elements and one of phosphorus (P), arsenic (As), and antimony (Sb) that are group V elements are combined, a ternary compound, and a quaternary compound. For example, the fin-type pattern 101 may include a semiconductor material. One of the elemental semiconductor material such as silicon and germanium, the IV-IV compound semiconductor, and the III-V compound semiconductor may be included.

According to some example embodiments, the first active pattern AP1 may be disposed on the active region AR of the substrate 100. The first active pattern AP1 may be disposed on the fin-type pattern 101. For example, the first active pattern AP1 may be an active pattern including a nanosheet or a nanowire. The first active pattern AP1 may include a plurality of first sheets ST1. The plurality of first sheets ST1 may be disposed on the substrate 100. The plurality of first sheets ST1 may be spaced apart from the substrate 100 in the first direction D1. The plurality of first sheets ST1 may be spaced apart from each other in the first direction D1. The plurality of first sheets ST1 may extend in the second direction D2.

According to some example embodiments, in the second direction D2, the first active pattern AP1 may be disposed between the first source/drain patterns 150. The first active pattern AP1 may be connected to the first source/drain pattern 150. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

According to some example embodiments, the second active pattern AP2 may be disposed on the active region AR of the substrate 100. The second active pattern AP2 may be disposed on the first active pattern AP1. The second active pattern AP2 may be spaced apart from the first active pattern AP1 in the first direction D1. For example, the second active pattern AP2 may be an active pattern including a nanosheet or a nanowire. The second active pattern AP2 may include a plurality of second sheets ST2. The plurality of second sheets ST2 may be disposed on the plurality of first sheets ST1. The plurality of second sheets ST2 may be spaced apart from each other in the first direction D1. The plurality of second sheets ST2 may extend in the second direction D2.

According to some example embodiments, in the second direction D2, the second active pattern AP2 may be disposed between the second source/drain patterns 250. The second active pattern AP2 may be connected to the second source/drain pattern 250.

For example, widths in the third direction D3 of the plurality of first sheets ST1 of the first active pattern AP1 and the plurality of second sheets AP2 of the second active pattern AP2 may become longer or shorter in proportion to a width in the third direction D3 of the fin-type pattern 101 disposed below the first active pattern AP1. The widths in the third direction D3 of each of the plurality of first sheets ST1 of the first active pattern AP1 and each of the plurality of second sheets AP2 of the second active pattern AP2 are illustrated as being identical to one another, but example embodiments are not limited thereto.

According to some example embodiments, the first active pattern AP1 and the second active pattern AP2 may include, for example, silicon or germanium, the elemental semiconductor materials. In addition, the first active pattern AP1 and the second active pattern AP2 may include a compound semiconductor and may include, for example, IV-IV compound semiconductor or III-V compound semiconductor.

The IV-IV compound semiconductor may be a binary compound, for example, including at least two or more of carbon (C), silicon (Si), germanium (Ge), and tin (Sn), a ternary compound, or a compound doped with a group IV element thereto.

The III-V compound semiconductor may be one of a binary compound formed, for example, by a combination of at least one of aluminum (Al), gallium (Ga), and indium (In) that are group III elements and one of phosphorus (P), arsenic (As), and antimony (Sb) that are group V elements, a ternary compound, and a quaternary compound.

According to some example embodiments, each of the first active pattern AP1 and the second active pattern AP2 may include an identical material to the fin-type pattern 101 and may also include a different material from the fin-type pattern 101. The fin-type pattern 101 may be a silicon fin-type pattern that includes silicon, and the first active pattern AP1 and the second active pattern AP2 may be silicon sheet patterns that include silicon. Each of the first active pattern AP1 and the second active pattern AP2 may not include p-type impurities or n-type impurities. The first active pattern AP1 and the second active pattern AP2 may include silicon alone (i.e., intrinsic silicon).

FIG. 2 illustrates that the first active pattern AP1 and the second active pattern AP2 include two of the first sheets ST1 and two of the second sheets ST2, respectively, but example embodiments are not limited thereto. For example, each of the first active pattern AP1 and the second active pattern AP2 may include three or more sheets. Moreover, the number of sheets ST1 of the first active pattern AP1 may not necessarily be the same as the number of sheets ST2 of the second active pattern AP2.

According to some example embodiments, the field insulating film 105 may be disposed in the field region FR. The field insulating film 105 may be disposed on the substrate 100. For example, the field insulating film 105 may be disposed between the fin-type pattern 101 overlapping the first active pattern AP1 in the first direction D1 and the fin-type pattern 101 overlapping the second active pattern AP2 in the first direction D1. In other words, the field insulating film 105 may be disposed on a portion of the substrate 100 not overlapping the first active pattern AP1 and the second active pattern AP2 in the first direction D1. The field insulating film 105 may fill at least a portion of the trench TR formed on the substrate 100. The term “fill” (or “fills,” or like terms) is intended to refer to either completely filling a defined space (e.g., the trench TR) or partially filling the defined space; that is, the defined space need not be entirely filled but may, for example, be partially filled or have voids or other spaces throughout.

According to some example embodiments, the field insulating film 105 may cover a sidewall of the fin-type pattern 101. An upper surface of the field insulating film 105 may be disposed to be flush with an upper surface of the fin-type pattern 101. Although not explicitly shown in the drawings, for another example, the field insulating film 105 may cover a portion alone of the sidewall of the fin-type pattern 101. In this case, a portion of the fin-type pattern 101 may protrude above the field insulating film 105 in the first direction D1, relative to the surface of the substrate 100 as a reference layer. For example, the field insulating film 105 may include an oxide film, a nitride layer, an oxynitride film, or a combination film thereof. The field insulating film 105 is illustrated as a single film, merely for convenience of description, and not limited thereto.

According to some example embodiments, the gate structures GS may be disposed on the substrate 100. Each gate structure GS may extend in the third direction D3. The gate structures GS may be spaced apart from one another in the second direction D2. The gate structures GS may be adjacent to each other in the second direction D2.

According to some example embodiments, the gate structure GS may be disposed on the first active pattern AP1 and the second active pattern AP2. For example, the gate structure GS may intersect the first active pattern AP1 and the second active pattern AP2.

According to some example embodiments, the gate structure GS may surround the first active pattern AP1 and the second active pattern AP2. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Specifically, a gate electrode 120 of the gate structure GS may surround (i.e., extend around) the plurality of first sheets ST1 and the plurality of second sheets ST2.

FIG. 1 illustrates that the gate electrode 120 of the gate structure GS is disposed across the active region AR and the field region FR, but example embodiments are not limited thereto. For example, the gate structure GS may not continuously extend in the third direction D3 across two active regions AR spaced apart in the third direction D3 with the field region FR in between and be separated in the field region FR. In this case, the gate structure GS extending in the third direction D3 and intersecting one active region AR and the gate structure GS extending in the third direction D3 and intersecting another active region AR may be spaced apart from each other in the third direction D3.

According to some example embodiments, the gate structure GS may include the gate electrode 120, a gate insulating film 130, a gate spacer 140, and a gate capping film 125.

According to some example embodiments, the gate electrode 120 may extend in the third direction D3. The gate electrode 120 may be disposed between the first source/drain patterns 150 adjacent to each other in the second direction D2. The gate electrode 120 may be disposed between the second source/drain patterns 250 adjacent to each other in the second direction D2.

According to some example embodiments, the gate electrode 120 may be formed on the fin-type pattern 101. The gate electrode 120 may intersect the fin-type pattern 101. The gate electrode 120 may surround the first active pattern AP1 and the second active pattern AP2.

According to some example embodiments, a portion of the gate electrode 120 may be disposed between the first sheets ST1 adjacent in the first direction D1 and between the second sheets ST2 adjacent in the first direction D1. In addition, a portion of the gate electrode 120 may be disposed between one of the first sheets ST1 and one of the second sheets ST2 that are adjacent in the first direction D1.

According to some example embodiments, the gate electrode 120 may include at least one of metal, metal alloy, conductive metal nitride, metal silicide, doped semiconductor material, conductive metal oxide, and conductive metal oxynitride. For example, the gate electrode 120 may include, but is not limited to, at least one of titanium nitride (TaN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. The conductive metal oxide and the conductive metal oxynitride may include, but are not limited to, an oxidized form of the materials described above.

According to some example embodiments, the gate electrode 120 may be disposed at opposite sides of the first source/drain pattern 150 and opposite sides of the second source/drain pattern 250 to be described below. The gate structure GS may be disposed at opposite sides of the first source/drain pattern 150 and opposite sides of the second source/drain pattern 250 in the second direction D2.

As an example, all the gate electrodes 120 disposed at the opposite sides of the first source/drain pattern 150 may be a normal gate electrode used as a gate of a transistor. As another example, the gate electrode 120 disposed at one side of the first source/drain pattern 150 may be used as a gate of a transistor, while the gate electrode 120 disposed at the other side of the first source/drain pattern 150 may be a dummy gate electrode.

According to some example embodiments, the gate insulating film 130 may extend along the upper surface of the field insulating film 105 and the upper surface of the fin-type pattern 101. The gate insulating film 130 may surround the first active pattern AP1 and the second active pattern AP2. The gate insulating film 130 may be disposed along perimeters of the first sheets ST1 and the second sheets ST2. The gate electrode 120 may be disposed on the gate insulating film 130. The gate insulating film 130 may be disposed between the gate electrode 120 and the first active pattern AP1. The gate insulating film 130 may be disposed between the gate electrode 120 and the second active pattern AP2.

According to some example embodiments, a portion of the gate insulating film 130 may be disposed between the first sheets ST1 adjacent in the first direction D1, between the second sheets ST2 adjacent in the first direction D1, and between the fin-type pattern 101 and one of the first sheets ST1 that are adjacent in the first direction D1. In addition, a portion of the gate insulating film 130 may be disposed between one of the first sheets ST1 and one of the second sheets ST2 that are adjacent to each other in the first direction D1.

According to some example embodiments, the gate insulating film 130 may include silicon oxide, silicon-germanium oxide, germanium oxide, silicon oxynitride, silicon nitride, or a high-permittivity material of which a dielectric constant is greater than that of silicon oxide. The high-permittivity material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate insulating film 130 is illustrated as a single film in FIGS. 2 to 5, merely for convenience of description, and not limited thereto. The gate insulating film 130 may include a plurality of films. The gate insulating film 130 may also include an interfacial layer disposed between the first active pattern AP1 or the second active pattern AP2 and the gate electrode 120 and a high-permittivity insulating film.

According to some example embodiments, the semiconductor device may include a negative capacitance (NC) FET using a negative capacitor. For example, the gate insulating film 130 may include a ferroelectric material film having ferroelectric properties and a paraelectric material film having paraelectric properties.

The ferroelectric material film may have negative capacitance, and the paraelectric material film may have positive capacitance. For example, when two or more capacitors are connected serially and a capacitance of each capacitor has a positive value, the total capacitance becomes less than the capacitance of each individual capacitor. In contrast, when at least one of the capacitances of two or more capacitors serially connected has a negative value, the total capacitance may have a positive value and be greater than an absolute value of each individual capacitance.

When the ferroelectric material film with negative capacitance and the paraelectric material film with positive capacitance are connected serially, the total capacitance value of the ferroelectric material film and the paraelectric material film serially connected may increase. Using the increasing total capacitance value, a transistor including the ferroelectric material film may have a subthreshold swing (SS) of less than 60 millivolts/decade (mV/dec) at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, hafnium zirconium oxide may be a material into which hafnium oxide is doped with zirconium (Zr). As another example, hafnium zirconium oxide may be also a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material film includes, a type of a dopant included in the ferroelectric material film may vary.

When the ferroelectric material film includes hafnium oxide, a dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 atomic percent (at %) of aluminum. Here, a ratio of a dopant may be a ratio of aluminum to the sum of hafnium and aluminum.

When the dopant is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may include 1 to 7 at % of gadolinium. When the dopant is zirconium (Zr), the ferroelectric material film may include 50 to 80 at % of zirconium.

The paraelectric material film may have paraelectric properties. The paraelectric material film may include, for example, at least one of silicon oxide and metal oxide with high permittivity. For example, the metal oxide included in the paraelectric material film may include, but is not limited to, at least one of hafnium oxide, zirconium oxide, and aluminum oxide.

The ferroelectric material film and the paraelectric material film may include an identical material. While the ferroelectric material film may have ferroelectric properties, the paraelectric material film may not have ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have thickness with a ferroelectric property. For example, the thickness of the ferroelectric material film may be, but is not limited to, 0.5 to 10 nanometers (nm). Since a threshold thickness representing a ferroelectric property may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which a plurality of ferroelectric material films and a plurality of paraelectric material films are stacked alternately.

According to some example embodiments, the gate spacer 140 may be disposed on a sidewall of the gate electrode 120. The gate spacer 140 may not be disposed between the fin-type pattern 101 and the first sheets ST1 and between the first sheets ST1 adjacent in the first direction D1. In the semiconductor device according to some example embodiments, the gate spacer 140 may include an outer spacer alone.

According to some example embodiments, the gate spacer 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. The gate spacer 140 is illustrated as a single film, merely for convenience of description, and not limited thereto.

According to some example embodiments, the gate capping film 125 may be disposed on the gate electrode 120 and the gate spacer 140. An upper surface of the gate capping film 125 may be placed flush with an upper surface of a second interlayer insulating film 192; that is, the upper surface of the gate capping film 125 may be coplanar with the upper surface of the second interlayer insulating film 192. Unlike the drawings, the gate capping film 125 may be disposed between the gate spacers 140. In this case, the upper surface of the gate capping film 125, an upper surface of the gate spacer 140, and the upper surface of the second interlayer insulating film 192 may be placed to be flush (i.e., coplanar).

According to some example embodiments, the gate capping film 125 may include, for example, at least one of silicon nitride (SiN), silicon oxynitride (SiON), silicon carbonitride (SiCN), silicon oxycarbonitride (SiOCN), and a combination thereof. The gate capping film 125 may include a material having an etch selectivity to the second interlayer insulating film 192.

According to some example embodiments, the first source/drain pattern 150 and the second source/drain pattern 250 may be disposed in the active region AR. The first source/drain pattern 150 and the second source/drain pattern 250 may be disposed in the first direction D1. For example, the first source/drain pattern 150 may be disposed more adjacent to the substrate 100 than the second source/drain pattern 250 in the first direction D1. The second source/drain pattern 250 may be disposed on the first source/drain pattern 150 in the first direction D1.

According to some example embodiments, the first source/drain pattern 150 and the second source/drain pattern 250 may have different conductivity types. For example, the first source/drain pattern 150 may have a p-type conductivity, and the second source/drain pattern 250 may have an n-type conductivity. The first source/drain pattern 150 may include a p-type dopant. The p-type dopant may include, but is not limited to, at least one of boron (B) and gallium (Ga). The second source/drain pattern 250 may include an n-type dopant. The n-type dopant may include, but is not limited to, at least one of phosphorus (P), arsenic (As), antimony (Sb), and bismuth (Bi). For another example, the first source/drain pattern 150 may have an n-type, and the second source/drain pattern 250 may have a p-type.

According to some example embodiments, the first source/drain pattern 150 may be connected to the first active pattern AP1. The first source/drain pattern 150 may be disposed between the first active patterns AP1 in the second direction D2. The first source/drain pattern 150 may be disposed between the gate electrodes 120 adjacent in the second direction D2. The first source/drain pattern 150 may be disposed on the fin-type pattern 101.

According to some example embodiments, the first source/drain pattern 150 may be a source/drain of a p-type MOS (PMOS) transistor. The first source/drain pattern 150 may be a source/drain of a transistor using the first active pattern AP1 as a channel region.

According to some example embodiments, at least a portion of the first source/drain pattern 150 may increase in width in the third direction D3 as the first source/drain pattern 150 extends farther from the substrate 100 in the first direction D1. Specifically, a portion of the first source/drain pattern 150 overlapping the fin-type pattern 101 in the third direction D3 may increase in width in the third direction D3 as the first source/drain pattern 150 extends farther from the substrate 100 in the first direction D1.

According to some example embodiments, in the third direction D3, the first source/drain pattern 150 may be disposed between the first fence films 310. For example, the sidewall of the first source/drain pattern 150SW disposed in the third direction D3 may be in contact with the first fence film 310. The sidewall of the first source/drain pattern 150 disposed in the third direction D3 may be covered by the first fence film 310. The first source/drain pattern 150 may overlap the first fence film 310 and the second fence film 320 in the third direction D3.

According to some example embodiments, the first source/drain pattern 150 may protrude above the first fence film 310 and the second fence film 320 toward the second source/drain pattern 250 in the first direction D1. For example, in the first direction D1, relative to a surface of the substrate 100, an upper surface 150US of the first source/drain pattern is disposed above an upper surface of the first fence film 310 and an upper surface of the second fence film 320.

According to some example embodiments, the first source/drain pattern 150 may include a multi-film. The first source/drain pattern 150 may include a first film 151 and a second film 152. For example, the first film 151 and the second film 152 may include silicon-germanium. In this case, each of the first film 151 and the second film 152 may include different fractions of germanium. For another example, the first film 151 and the second film 152 may include doped p-type impurities. In this case, each of the first film 151 and the second film 152 may include different concentrations of impurities.

According to some example embodiments, the first film 151 may be disposed along a surface of a recess 150R of the first source/drain pattern on the fin-type pattern 101. For example, the first film 151 may be conformally formed along the surface of the recess 150R of the first source/drain pattern. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The recess 150R of the first source/drain pattern may decrease in width in the third direction D3 as the recess 150R extends closer to the substrate 100 in the first direction D1. The first film 151 may be U-shaped. The first film 151 may have a shape convexly curving toward the substrate 100. The first film 151 may surround at least a portion of the second film 152. The first film 151 may cover at least a portion of a sidewall of the second film 152. For example, the first film 151 may cover an entire portion of the sidewall of the second film 152 disposed in the second direction D2 and cover a portion of the sidewall of the second film 152 disposed in the third direction D3.

According to some example embodiments, the second film 152 may be disposed on the first film 151. The second film 152 may fill the recess 150R of the first source/drain pattern on the first film 151. The second film 152 may include a first epitaxial film 152a and a second epitaxial film 152b.

According to some example embodiments, the first epitaxial film 152a may be a portion of the second film 152 which overlaps the first film 151 in the third direction D3. The first epitaxial film 152a may be surrounded by the first film 151. The first epitaxial film 152a may be disposed below the second epitaxial film 152b in the first direction D1. The first epitaxial film 152a may have a shape extending in the first direction D1 toward the first film 151 from the second epitaxial film 152b. For example, the first film 151 may have a U-shape, and the first epitaxial film 152a may fill a recess formed by the U-shape of the first film 151. In the third direction D3, a width of the first epitaxial film 152a may be less than a width of the second epitaxial film 152b.

According to some example embodiments, the second epitaxial film 152b may be disposed on the first epitaxial film 152a in the first direction D1. The second epitaxial film 152b may not overlap the first film 151 in the third direction D3. The second epitaxial film 152b may overlap the first film 151 in the second direction D2. However, example embodiments are not limited thereto. For example, the second epitaxial film 152b may not overlap the first film 151 even in the second direction D2. In the third direction D3, the width of the second epitaxial film 152b may be greater than the width of the first epitaxial film 152a.

According to some example embodiments, the second source/drain pattern 250 may be electrically connected to the second active pattern AP2. The second source/drain pattern 250 may be disposed between the second active patterns AP2 in the second direction D2. The second source/drain pattern 250 may be disposed between the gate electrodes 120 adjacent in the second direction D2. The second source/drain pattern 250 may be disposed on a first interlayer insulating film 191. The second source/drain pattern 250 may be spaced apart from the first source/drain pattern 150 in the first direction D1.

According to some example embodiments, the second source/drain pattern 250 may be a source/drain of an n-type MOS (NMOS) transistor. The second source/drain pattern 250 may be a source/drain of a transistor using the second active pattern AP2 as a channel region.

According to some example embodiments, on a cross-section including the first direction D1 and the third direction D3, a sidewall of the second source/drain pattern 250 may be surrounded by a second source/drain etch stop film 162. For example, on the cross-section including the first direction D1 and the third direction D3, whereas the first fence film 310 and the second fence film 320 are disposed on the sidewall of the first source/drain pattern 150, the sidewall of the second source/drain pattern 250 may be in contact with the second source/drain etch stop film 162 without a separate fence film.

According to some example embodiments, in the third direction D3, a width W250 of the second source/drain pattern 250 may be greater than a width W150 of the first source/drain pattern 150. This may be because a separate fence film is not disposed on the sidewall of the second source/drain pattern 250, while the first fence film 310 and the second fence film 320 are disposed on the sidewall of the first source/drain pattern 150 on the cross-section including the first direction D1 and the third direction D3.

According to some example embodiments, in the first direction D1, a height H150 of the first source/drain pattern may be greater than a height H250 of the second source/drain pattern. In this case, the height H150 of the first source/drain pattern 150 may refer to a distance between a lowermost point of the first source/drain pattern 150 which is most adjacent to the substrate 100 in the first direction D1 and an uppermost point of the first source/drain pattern 150 which is spaced most apart from the substrate 100. Similarly, the height H250 of the second source/drain pattern 250 may refer to a distance between a lowermost point of the second source/drain pattern 250 which is most adjacent to the substrate 100 in the first direction D1 and an uppermost point of the second source/drain pattern 250 which is spaced most apart from the substrate 100.

According to some example embodiments, since the height H150 of the first source/drain pattern 150 is relatively large, the second film 152 of the first source/drain pattern 150 may also be formed on the first film 151 to be deep enough to overlap the first active pattern AP1 in the second direction D2. As the second film 152 overlaps the first active pattern AP1 sufficiently in the second direction D2, a channel strain may be applied effectively to the first active pattern AP1.

According to some example embodiments, a first source/drain etch stop film 161 and the first interlayer insulating film 191 may be disposed on the first source/drain pattern 150. The first source/drain etch stop film 161 may extend along the upper surface 150US of the first source/drain pattern 150, the upper surface of the first fence film 310, the upper surface and an outer sidewall of the second fence film 320, and the upper surface of the field insulating film 105. In addition, the first source/drain etch stop film 161 may extend along the gate insulating film 130 disposed between the first sheet ST1 and the second sheet ST2 that are adjacent in the first direction D1.

According to some example embodiments, the first source/drain etch stop film 161 may not extend along the sidewall of the first source/drain pattern 150 and may extend along perimeters of the first fence film 310 and the second fence film 320.

According to some example embodiments, the first source/drain etch stop film 161 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and a combination thereof.

According to some example embodiments, the first interlayer insulating film 191 may be disposed on the first source/drain etch stop film 161. The first interlayer insulating film 191 may be formed on the field insulating film 105. In the first direction D1, the first interlayer insulating film 191 may be disposed between the first source/drain pattern 150 and the second source/drain pattern 250. The first interlayer insulating film 191 may cover a lower surface 250BS of the second source/drain pattern 250.

According to some example embodiments, the first interlayer insulating film 191 may include, for example, at least one of silicon oxide, silicon nitride, silicon oxynitride, and a low-permittivity material. For example, the low-permittivity material may include, but is not limited to, fluorinated tetraethyl orthosilicate (FTEOS), hydrogen silsesquioxane (HSQ), bis-benzocyclobutene (BCB), tetramethyl orthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof.

According to some example embodiments, the second source/drain etch stop film 162 and the second interlayer insulating film 192 may be disposed on the second source/drain pattern 250. The second source/drain etch stop film 162 may extend along an upper surface of the second source/drain pattern 250, the sidewall of the second source/drain pattern 250, and an upper surface of the first interlayer insulating film 191. The second interlayer insulating film 192 may not cover an upper surface of the gate structure GS. For example, the upper surface of the second interlayer insulating film 192 may be placed flush (i.e., coplanar) with the upper surface of the gate structure GS.

In addition to the above descriptions, the descriptions of the second source/drain etch stop film 162 and the second interlayer insulating film 192 are substantially identical to the descriptions of the first source/drain etch stop film 161 and the first interlayer insulating film 191 and are thus omitted.

According to some example embodiments, a first source/drain contact 171 may be disposed on the first source/drain pattern 150. The first source/drain contact 171 may be electrically connected to the first source/drain pattern 150. The first source/drain contact 171 may penetrate (i.e., extend in or through) the first interlayer insulating film 191 and the first source/drain etch stop film 161 to be electrically connected to the first source/drain pattern 150. In the first direction D1, the first source/drain contact 171 may not completely penetrate the first interlayer insulating film 191. The first source/drain contact 171 may be embedded within the first interlayer insulating film 191.

According to some example embodiments, the first source/drain contact 171 may include a first source/drain contact barrier film 171a and a first source/drain contact filling film 171b positioned on the first source/drain contact barrier film 171a. The first source/drain contact barrier film 171a may extend along a sidewall and a bottom surface of the first source/drain contact filling film 171b.

According to some example embodiments, based on an upper surface of the substrate 100 as a reference layer, an upper surface of the first source/drain contact barrier film 171a is illustrated to be positioned substantially flush (i.e., coplanar) with an upper surface of the first source/drain contact filling film 171b but is not limited thereto. Unlike as shown in the drawings, based on the upper surface of the substrate 100, the upper surface of the first source/drain contact barrier film 171a may be lower than the upper surface of the first source/drain contact filling film 171b.

According to some example embodiments, the first source/drain contact barrier film 171a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a two-dimensional (2D) material. In the semiconductor device according to some example embodiments, the 2D material may be a metallic material and/or a semiconductor material. The 2D material may include a 2D allotrope or a 2D compound, and may include, for example, at least one of graphene, molybdenum disulfide (MoS2), molybdenum diselenide (MoSe2), tungsten diselenide (WSe2), or tungsten disulfide (WS2) but is not limited thereto. In other words, the 2D materials described above are enumerated merely for example, and thus the 2D material that may be included in the semiconductor device of the present disclosure is not limited to the aforementioned materials.

According to some example embodiments, the first source/drain contact filling film 171b may include, for example, at least one of aluminum (Al), tungsten (W), cobalt (Co), ruthenium (Ru), silver (Ag), gold (Au), manganese (Mn), or molybdenum (Mo).

According to some example embodiments, the first source/drain contact 171 is illustrated to include a plurality of conductive films but is not limited thereto. Unlike as shown in the drawings, the first source/drain contact 171 may also be a single film.

According to some example embodiments, a second source/drain contact 172 may be disposed on the second source/drain pattern 250. The second source/drain contact 172 may be electrically connected to the second source/drain pattern 250. The second source/drain contact 172 may penetrate (i.e., extend in or through) the second interlayer insulating film 192 and the second source/drain etch stop film 162 to be electrically connected to the second source/drain pattern 250. In the first direction D1, the second source/drain contact 172 may completely penetrate the second interlayer insulating film 192.

According to some example embodiments, the second interlayer insulating film 192 may not cover an upper surface of the second source/drain contact 172. As an example, the upper surface of the second source/drain contact 172 may not protrude above the upper surface of the gate structure GS. The upper surface of the second source/drain contact 172 may be placed flush with the upper surface of the gate structure GS. Unlike the drawings, as another example, the upper surface of the second source/drain contact 172 may protrude above the upper surface of the gate structure GS.

According to some example embodiments, the second source/drain contact 172 may include a second source/drain contact barrier film 172a and a second source/drain contact filling film 172b positioned on the second source/drain contact barrier film 172a. The second source/drain contact barrier film 172a may extend along a sidewall and a bottom surface of the second source/drain contact filling film 172b. The descriptions of the second source/drain contact barrier film 172a and the second source/drain contact filling film 172b are substantially identical to the descriptions of the first source/drain contact barrier film 171a and the first source/drain contact filling film 171b and are thus omitted.

According to some example embodiments, the first fence film 310 and the second fence film 320 may be disposed on the sidewall of the first source/drain pattern 150 in the third direction D3. The first fence film 310 and the second fence film 320 may overlap the field insulating film 105 in the first direction D1. The first fence film 310 and the second fence film 320 may prevent the first source/drain pattern 150 when being formed by epitaxial growth from increasing in width in the third direction D3.

According to some example embodiments, in the third direction D3, the first fence film 310 may be disposed between the first source/drain pattern 150 and the second fence film 320. For example, an inner sidewall of the first fence film 310 may be in contact with the first source/drain pattern 150 and an outer sidewall of the first fence film 310 may be in contact with the second fence film 320.

According to some example embodiments, the first fence film 310 may be formed at an identical level with the gate spacer 140 in the first direction D1, with respect to the surface of the substrate 100. In this case, being formed at an identical level may indicate being formed by an identical manufacturing process. The first fence film 310 may include an identical material to the gate spacer 140. For example, the first fence film 310 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof.

According to some example embodiments, the second fence film 320 may be disposed on the first fence film 310. Specifically, the second fence film 320 may be disposed on the outer sidewall of the first fence film 310 in the third direction D3. The second fence film 320 may include an insulating material. For example, the second fence film 320 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof.

According to some example embodiments, each of the first fence film 310 and the second fence film 320 may include different materials. For example, the first fence film 310 may include silicon oxycarbide (SiOC), and the second fence film 320 may include silicon nitride (SiN). However, example embodiments are not limited thereto, and materials included in the first fence film 310 and the second fence film 320 may also be changed variously depending on example embodiments.

FIG. 3 illustrates that heights of the first fence film 310 and the second fence film 320 are identical in the first direction D1, but example embodiments are not limited thereto. For example, in the first direction D1, the height of the first fence film 310 may be greater than the height of the second fence film 320. For another example, in the first direction D1, the height of the first fence film 310 may be less than the height of the second fence film 320.

According to some example embodiments, a first etch stop film 196, a third interlayer insulating film 193, a second etch stop film 197, and a fourth interlayer insulating film 194 may be disposed on the second interlayer insulating film 192, the gate structure GS, and the second source/drain contact 172. The first etch stop film 196, the third interlayer insulating film 193, the second etch stop film 197, and the fourth interlayer insulating film 194 may be stacked on the second interlayer insulating film 192, the gate structure GS, and the second source/drain contact 172 sequentially in the first direction D1.

According to some example embodiments, the first etch stop film 196 may include a material having an etch selectivity to the third interlayer insulating film 193. For example, the first etch stop film 196 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AIO), aluminum nitride (AlN), aluminum oxycarbide (AlOC), or a combination thereof. The first etch stop film 196 is illustrated as, but is not limited to, a single film. Unlike as shown in the drawings, the first etch stop film 196 may also not be formed. For example, the third interlayer insulating film 193 may include at least one of silicon oxide, silicon nitride, silicon oxynitride, silicon oxynitride, or a low-permittivity material.

According to some example embodiments, the second etch stop film 197 may be disposed between the third interlayer insulating film 193 and the fourth interlayer insulating film 194. The second etch stop film 197 may extend along an upper surface of the third interlayer insulating film 193. The second etch stop film 197 may include a material having an etch selectivity to the fourth interlayer insulating film 194. The description of a material included in the second etch stop film 197 may be substantially identical to the description of the first etch stop film 196. The description of the fourth interlayer insulating film 194 may be substantially identical to the description of the third interlayer insulating film 193.

According to some example embodiments, a gate contact 180 may be disposed on the gate electrode 120. The gate contact 180 may penetrate the gate capping film 125 to be electrically connected to the gate electrode 120. The gate contact 180 may penetrate the first etch stop film 196 and the third interlayer insulating film 193. The gate contact 180 may be electrically connected to a wiring line 201.

As an example, an upper surface of the gate contact 180 may protrude above the upper surface of the gate structure GS in the first direction D1. Unlike as shown in the drawings, as another example, the upper surface of the gate contact 180 may be placed flush (i.e., coplanar) with the upper surface of the gate structure GS.

According to some example embodiments, the gate contact 180 may include a gate contact barrier film 180a and a gate contact filling film 180b positioned on the gate contact barrier film 180a. The description of materials included in the gate contact barrier film 180a and the gate contact filling film 180b may be identical to the description of materials included in the first source/drain contact barrier film 171a and the first source/drain contact filling film 171b, respectively.

According to some example embodiments, a wiring via 175 may be disposed within the third interlayer insulating film 193. The wiring via 175 may penetrate the first etch stop film 196 to be directly electrically connected to the second source/drain contact 172. The wiring via 175 may electrically connect the second source/drain contact 172 and the wiring line 201. Though not explicitly illustrated, the wiring via 175 may penetrate the third interlayer insulating film 193, the first etch stop film 196, the second interlayer insulating film 192, the second source/drain etch stop film 162, the first interlayer insulating film 191, and the first source/drain etch stop film 161 to be electrically connected to the first source/drain contact 171.

According to some example embodiments, the wiring via 175 may include a via barrier film 175a and a via filling film 175b. The via barrier film 175a may extend along a sidewall and a bottom surface of the via filling film 175b. For example, the via barrier film 175a may include at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a 2D material. For example, the via filling film 175b may include at least one of aluminum (Al), tungsten (W), cobalt (Co), ruthenium (Ru), copper (Cu), silver (Ag), gold (Au), manganese (Mn), or molybdenum (Mo).

According to some example embodiments, the wiring line 201 may be disposed within the fourth interlayer insulating film 194. The wiring line 201 may be connected to the gate contact 180. The wiring line 201 may be connected to the first source/drain contact 171 or the second source/drain contact 172 through the wiring via 175.

According to some example embodiments, the wiring line 201 may include a wiring barrier film 201a and a wiring filling film 201b. For example, the wiring barrier film 201a may include at least one of metal, conductive metal nitride, conductive metal carbide, conductive metal oxide, conductive metal carbonitride, and a 2D material. For example, the wiring filling film 201b may include at least one of metal or metal alloy. The descriptions of the wiring barrier film 201a and the wiring filling film 201b of the wiring line 201 may be substantially identical to the descriptions of the via barrier film 175a and the via filling film 175b of the wiring via 175. The wiring line 201 is illustrated to have a structure of a multi-conductive film but is not limited thereto. Unlike as shown in the drawings, the wiring line 201 may have a single conductive film structure.

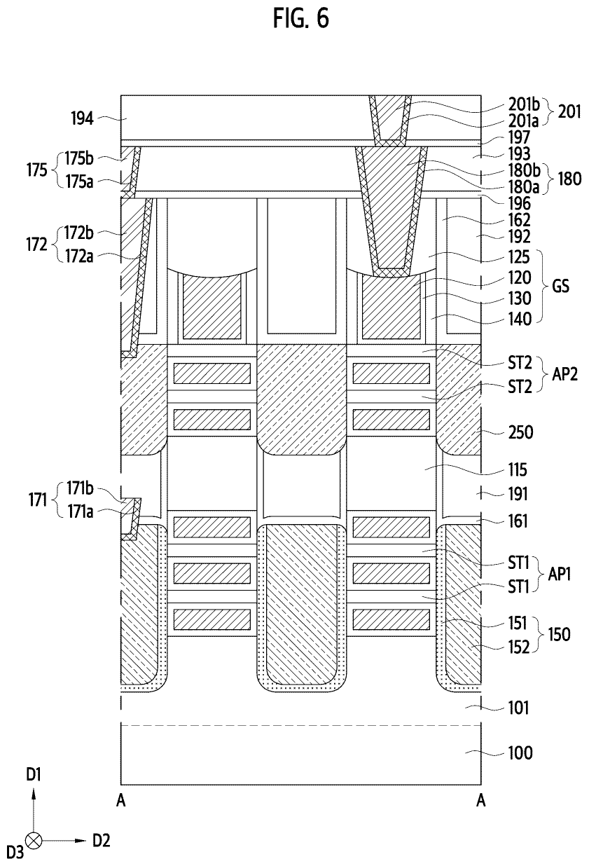

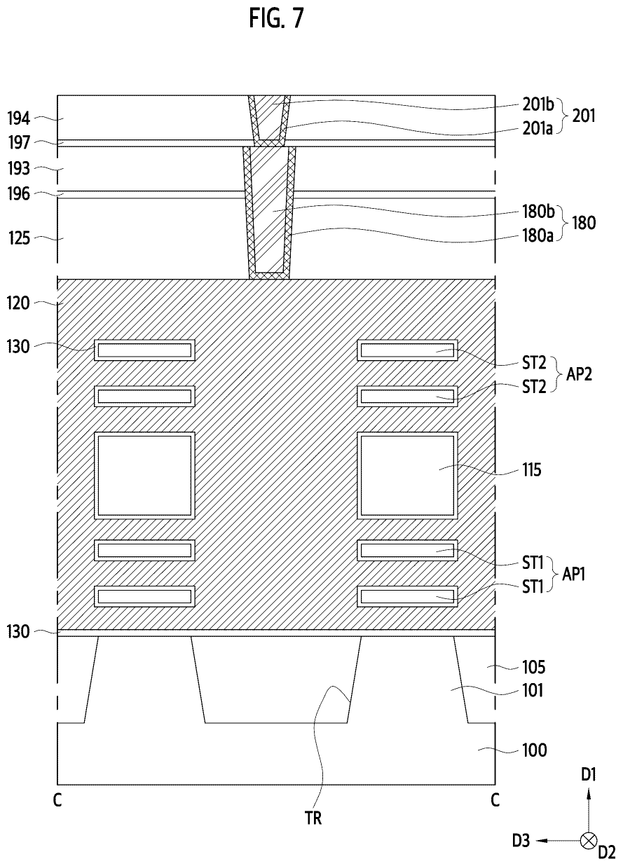

FIG. 6 is a schematic cross-sectional view taken along line A-A of FIG. 1 for illustrating a semiconductor device according to some other example embodiments. FIG. 7 is a schematic cross-sectional view taken along line C-C of FIG. 1 for illustrating a semiconductor device according to some other example embodiments. For convenience of description, differences from the descriptions relating to FIGS. 1 to 5 are mainly described.

Referring to FIGS. 6 and 7, the semiconductor device according to some example embodiments may include an isolation insulating film 115. The isolation insulating film 115 may be disposed between the first active pattern AP1 and the second active pattern AP2 in the first direction D1. The isolation insulating film 115 may be spaced apart from the plurality of first sheets ST1 and the plurality of second sheets ST2 in the first direction D1.

According to some example embodiments, the isolation insulating film 115 may be surrounded by the gate insulating film 130 and the gate electrode 120 of the gate structure GS. The gate insulating film 130 may surround the isolation insulating film 115. For example, the gate insulating film 130 may cover surfaces of the isolation insulating film 115 which are exposed in the first direction D1 and the third direction D3. The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. A surface of the isolation insulating film 115 which is exposed in the second direction D2 may be covered by the first source/drain etch stop film 161 rather than the gate insulating film 130. However, example embodiments are not limited thereto. For example, the gate insulating film 130 may also cover even the surface of the isolation insulating film 115 which is exposed in the second direction D2. For another example, the isolation insulating film 115 may also extend longitudinally in the third direction D3. In this case, the gate electrode 120 may be isolated into an upper gate electrode and a lower gate electrode by the isolation insulating film 115.

According to some example embodiments, the isolation insulating film 115 may include an insulating material. For example, the isolation insulating film 115 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof.

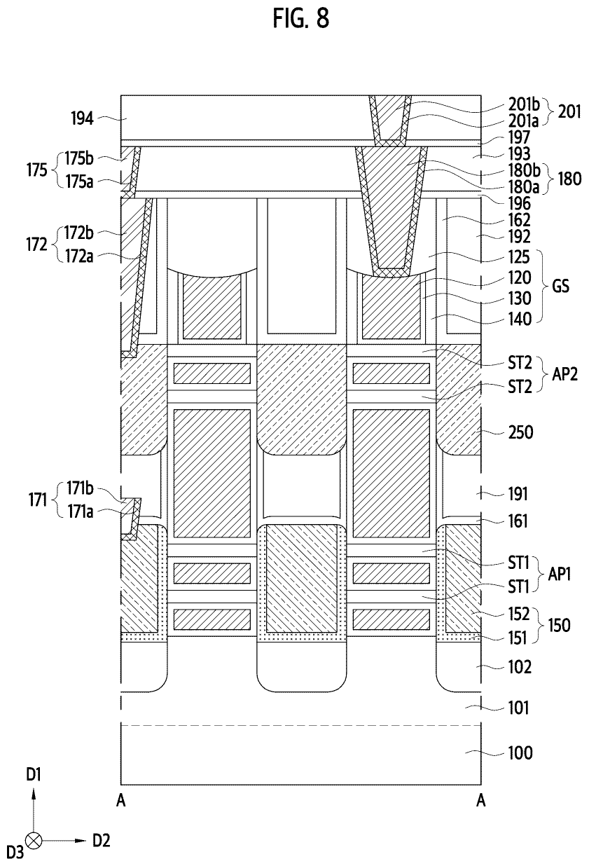

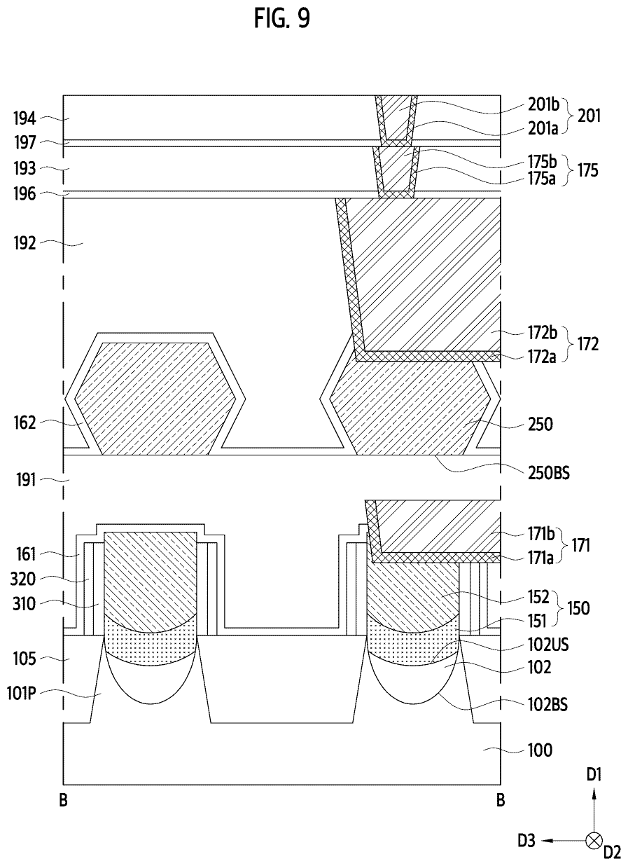

FIG. 8 is a schematic cross-sectional view taken along line A-A of FIG. 1 for illustrating a semiconductor device according to still other example embodiments. FIG. 9 is a schematic cross-sectional view taken along line B-B of FIG. 1 for illustrating a semiconductor device according to still other example embodiments. For convenience of description, differences from the descriptions relating to FIGS. 1 to 5 are mainly described.

Referring to FIGS. 8 and 9, the semiconductor device according to some example embodiments may include a supporter 102.

According to some example embodiments, the supporter 102 may be disposed within the fin-type pattern 101. The supporter 102 may be surrounded by the fin-type pattern 101. The supporter 102 may be disposed below the first source/drain pattern 150 and the second source/drain pattern 250. For example, the supporter 102 may be disposed below the first source/drain pattern 150 and the second source/drain pattern 250 to which backside source/drain contacts are not connected. The supporter 102 may include, for example, silicon-germanium (SiGe).

According to some example embodiments, both a lower surface 102BS of the supporter and an upper surface 102US of the supporter may curve toward the upper surface of the substrate 100. A radius of curvature of the upper surface 102US of the supporter may be less than a radius of curvature of the lower surface 102BS of the supporter. In other words, a degree at which the upper surface 102US of the supporter curves toward the substrate 100 may be less than a degree at which the lower surface 102BS of the supporter curves toward the substrate 100.

According to some example embodiments, since the curvature of the upper surface 102US of the supporter is relatively small, the first film 151 of the first source/drain pattern 150 disposed on the supporter 102 may be stably formed along the upper surface 102US of the supporter.

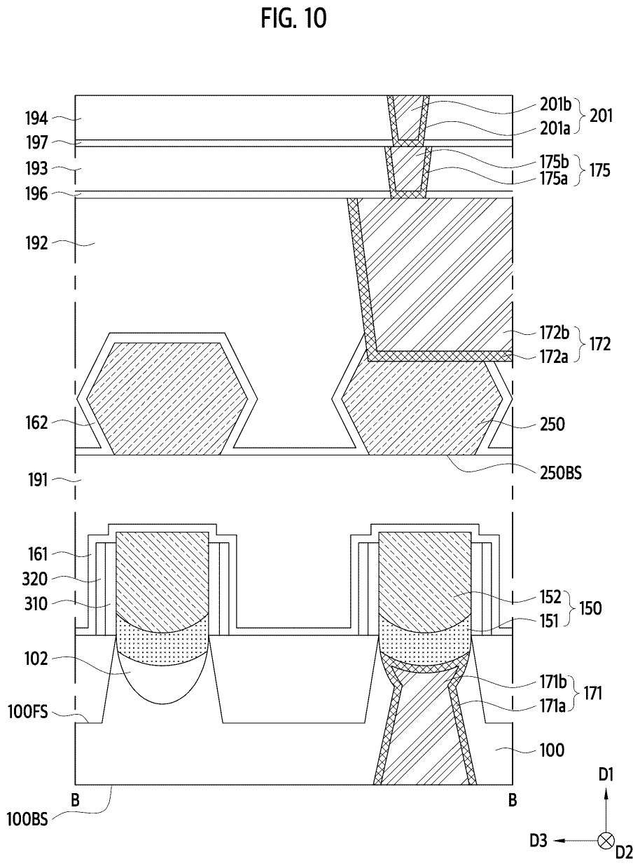

FIG. 10 is a schematic cross-sectional view taken along line B-B of FIG. 1 for illustrating a semiconductor device according to still other example embodiments. For convenience of description, differences from the descriptions relating to FIGS. 8 and 9 are mainly described.

Referring to FIG. 10, the first source/drain contact 171 may be disposed toward the first source/drain pattern 150 from a back surface 100BS of the substrate 100. In this case, the back surface 100BS of the substrate 100 may refer to a surface opposite in the first direction D1 to a front surface 100FS of the substrate 100 facing the first source/drain pattern 150. In other words, the first source/drain contact 171 may not be disposed within the first interlayer insulating film 191 and may penetrate the substrate 100 to extend up to a lower surface of the first source/drain pattern 150.

According to some example embodiments, while the first source/drain contact 171 connected below the first source/drain pattern 150 is formed, the supporter 102 disposed below the first source/drain pattern 150 may be removed. In a space where the supporter 102 is removed, the first source/drain contact 171 may be formed.

According to some example embodiments, by forming the first source/drain contact 171 to be penetrated from the back surface 100BS of the substrate, a wiring structure of a semiconductor device may be simplified, accordingly lowering a process level of difficulty.

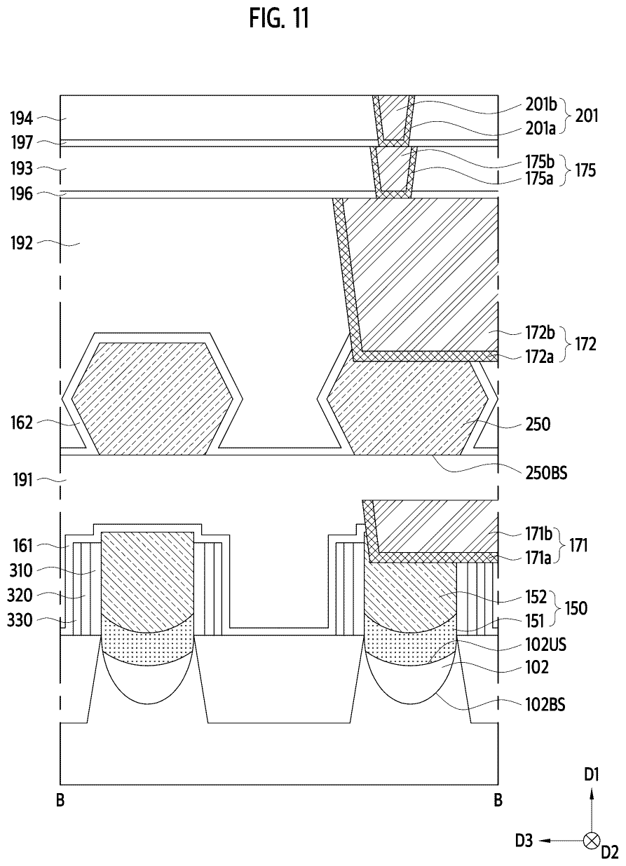

FIG. 11 is a schematic cross-sectional view taken along line B-B of FIG. 1 for illustrating a semiconductor device according to still other example embodiments. For convenience of description, differences from descriptions relating to FIGS. 8 and 9 are mainly described.

Referring to FIG. 11, the semiconductor device according to some example embodiments may include a third fence film 330. The third fence film 330 may be disposed on the second fence film 320. Specifically, the third fence film 330 may be disposed on the outer sidewall of the second fence film 320 in the third direction D3. The third fence film 330 may include an insulating material. For example, the third fence film 330 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof.

According to some example embodiments, the third fence film 330 may include a different material from each of the first fence film 310 and the second fence film 320. The third fence film 330 may be formed on the second fence film 320 while the supporter 102 is formed.

According to some example embodiments, in the third direction D3, as the first fence film 310, the second fence film 320, and the third fence film 330 is disposed in a multi-film structure on the sidewall of the first source/drain pattern 150, excessive epitaxial growth in the third direction D3 may be restrained when the first source/drain pattern 150 is formed.

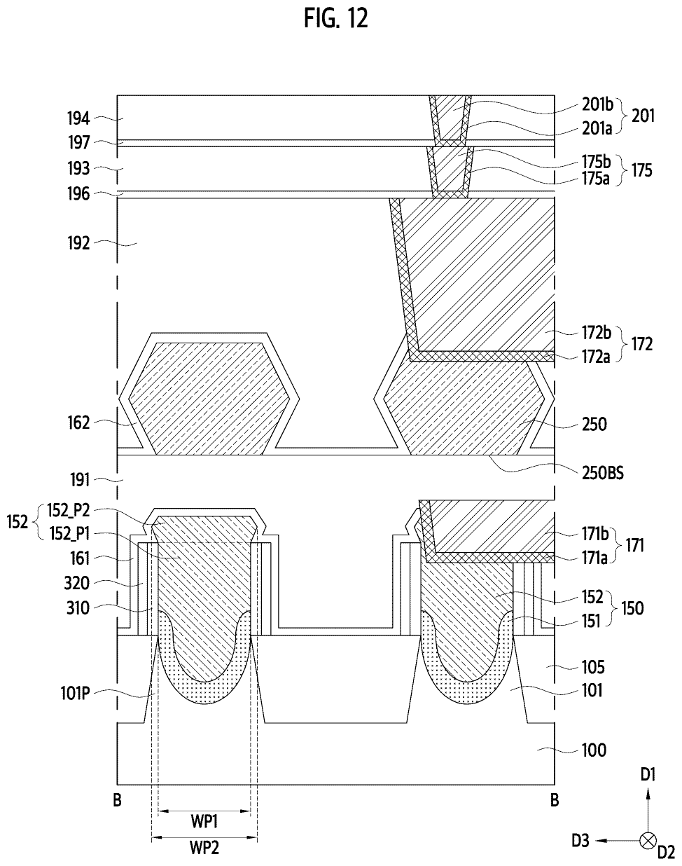

FIG. 12 is a schematic cross-sectional view taken along line B-B of FIG. 1 for illustrating a semiconductor device according to still other example embodiments. For convenience of description, differences from descriptions relating to FIGS. 1 to 5 are mainly described.

Referring to FIG. 12, the second film 152 of the first source/drain pattern 150 may include a first portion 152_P1 and a second portion 152_P2. The first portion 152_P1 and the second portion 152_P2 may be divided based on the upper surface of the first fence film 310 and the upper surface of the second fence film 320. For example, the first portion 152_P1 may refer to a portion of the second film 152 that is at or lower than the upper surface of the first fence film 310 and the upper surface of the second fence film 320 in the first direction D1, with respect to the surface of the substrate 100. The second portion 152_P2 may refer to a portion of the second film 152 that is at or higher than the upper surface of the first fence film 310 and the upper surface of the second fence film 320 in the first direction D1, relative to the surface of the substrate 100.

According to some example embodiments, the first portion 152_P1 may be disposed below the second portion 152_P2. The first portion 152_P1 may be disposed between the second portion 152_P2 and the first film 151. At least a portion of the first portion 152_P1 may overlap the first fence film 310 and the second fence film 320 in the third direction D3.

According to some example embodiments, the second portion 152_P2 may be disposed above the first portion 152_P1. The second portion 152_P2 may protrude toward the second source/drain pattern 250 from the first portion 152_P1. The second portion 152_P2 may not overlap the first fence film 310 and the second fence film 320 in the third direction D3. The second portion 152_P2 may gradually increase and decrease back in width in the third direction D3 as being farther from the first portion 152_P1 in the first direction D1. In other words, the width of the second portion 152_P2 may not be uniform in the third direction D3 and may be maximum at a specific height of the first direction D1.

According to some example embodiments, in the third direction D3, a width WP2 of the second portion 152_P2 may be greater than a width WP1 of the first portion 152_P1. In this case, the width WP2 of the second portion 152_P2 may indicate the maximum width of the second portion 152_P2. The first portion 152_P1 may overlap the first fence film 310 and the second fence film 320 which limit epitaxial growth of the second film 152 in the third direction D3 and thus have a uniform width in the third direction D3. In contrast, the second portion 152_P2 may not overlap the first fence film 310 and the second fence film 320 which limit epitaxial growth of the second film 152 in the third direction D3 and thus may have a greater width compared to the first portion 152_P1 in the third direction D3. The second portion 152_P2 may overlap the first fence film 310 in the first direction D1. In another example embodiment, the second portion 152_P2 may overlap the first fence film 310 and the second fence film 320 in the first direction D1.

According to some example embodiments, in the third direction D3, the width WP2 of the second portion 152_P2 of the second film 152 may be less than the width of the second source/drain pattern 250. Since a fence film limiting epitaxial growth is not disposed on the sidewall of the second source/drain pattern 250, the second source/drain pattern 250 may have a greater width than the second portion 152_P2 protruding upward and growing more after epitaxial growth in the third direction D3 is limited by the first fence film 310 and the second fence film 320.

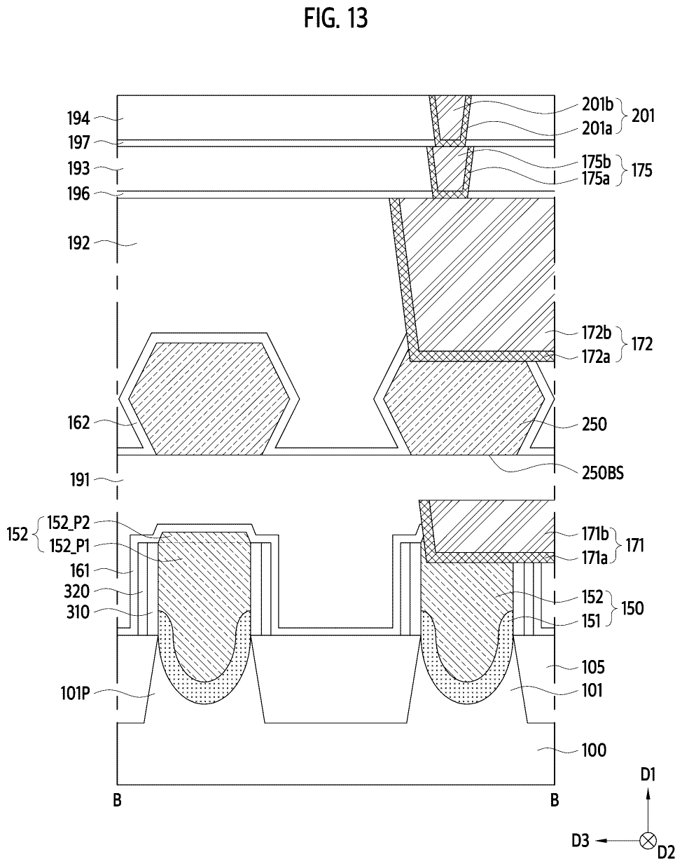

FIG. 13 is a schematic cross-sectional view taken along line B-B of FIG. 1 for illustrating a semiconductor device according to still other example embodiments. For convenience of description, differences from descriptions relating to FIGS. 1 to 5 are mainly described.

Referring to FIG. 13, the second portion 152_P2 may decrease in width in the third direction D3 as the second portion 152_P2 extends farther from the first portion 152_P1 in the first direction D1. In other words, on a cross-section including the first direction D1 and the third direction D3, the second portion 152_P2 may have a trapezoidal shape. The second film 152 of which epitaxial growth in the third direction D3 is limited by the first fence film 310 and the second fence film 320 may not increase but decrease in width in the third direction D3 due to a decreasing growth speed, even though protruding more than the upper surfaces of the first fence film 310 and the second fence film 320 toward the second source/drain pattern 250.

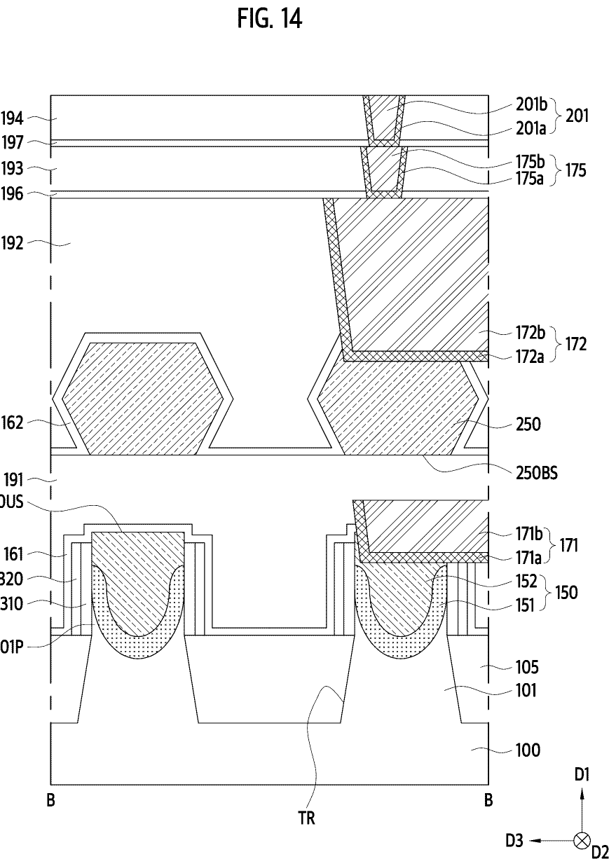

FIG. 14 is a schematic cross-sectional view taken along line B-B of FIG. 1 for illustrating a semiconductor device according to still other example embodiments. For convenience of description, differences from being described with reference to FIGS. 1 to 5 are mainly described.

Referring to FIG. 14, at least a portion of the protrusion part 101P of the fin-type pattern 101 may overlap the first fence film 310 and the second fence film 320 in the third direction D3. In other words, in the third direction D3, the protrusion part 101P may be disposed between the first source/drain pattern 150 and the first fence film 310. When the recess (150R of FIG. 3) of the first source/drain pattern, in which the first source/drain pattern 150 is formed, is formed from above the upper surface of the field insulating film 105, the protrusion part 101P may remain between the first source/drain pattern 150 and the first fence film 310.

According to some example embodiments, by controlling a depth of the recess (150R of FIG. 3) of the first source/drain pattern 150 and a position of the protrusion part 101P in the first direction D1, a degree to which the first source/drain pattern 150 and the first active pattern AP1 overlap in the second direction D2 may be controlled. Accordingly, by controlling a degree to which the second film 152 overlaps the first active pattern AP1 in the second direction D2, a channel strain applied to the first active pattern AP1 may be effectively controlled.

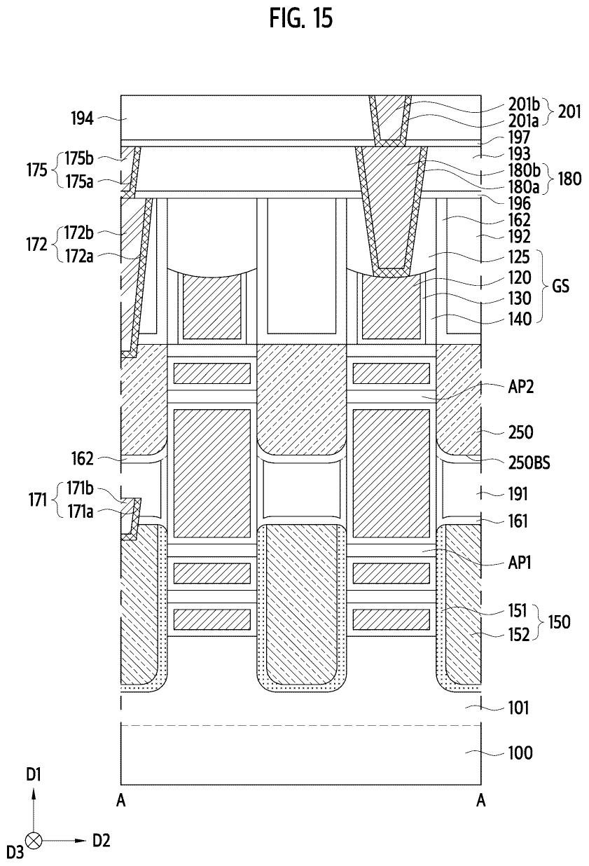

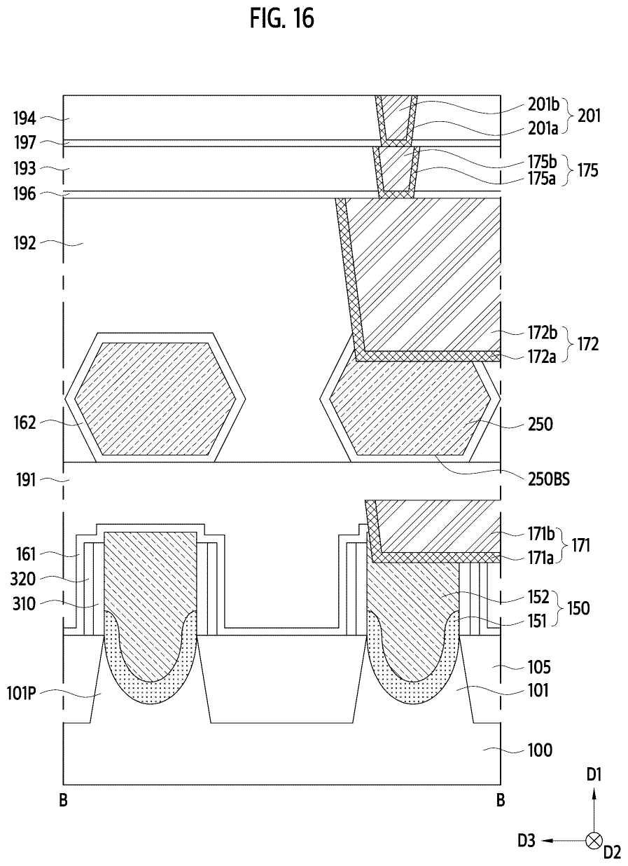

FIG. 15 is a schematic cross-sectional view taken along line A-A of FIG. 1 for illustrating a semiconductor device according to still other example embodiments. FIG. 16 is a schematic cross-sectional view taken along line B-B of FIG. 1 for illustrating a semiconductor device according to still other example embodiments. For convenience of description, differences from descriptions relating to FIGS. 1 to 5 are mainly described.

Referring to FIGS. 15 and 16, the second source/drain etch stop film 162 may cover the lower surface 250BS of the second source/drain pattern 250. On a cross-section including the first direction D1 and the third direction D3, the second source/drain etch stop film 162 may be formed along an entire perimeter of the second source/drain pattern 250.

According to some example embodiments, the second source/drain etch stop film 162 covering the lower surface 250BS of the second source/drain pattern may be connected to the first source/drain etch stop film 161 extending in the first direction D1. Accordingly, on a cross-section including the first direction D1 and the second direction D2, the first source/drain etch stop film 161 and the second source/drain etch stop film 162 may be connected between the first source/drain pattern 150 and the second source/drain pattern 250 which are spaced apart in the first direction D1 and may form a loop shape.

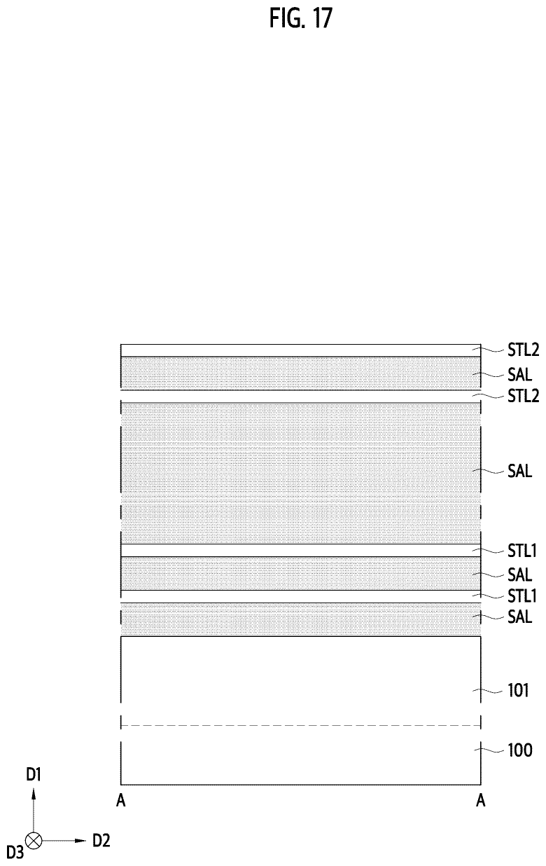

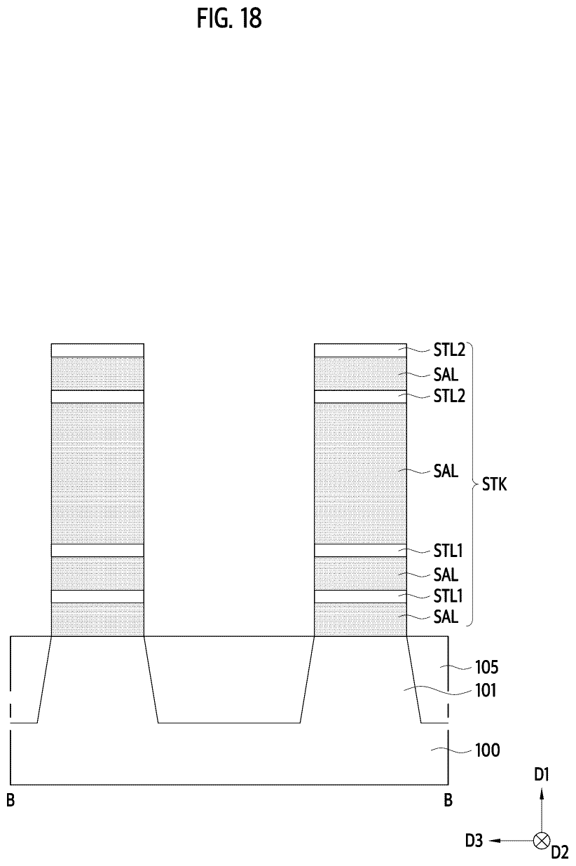

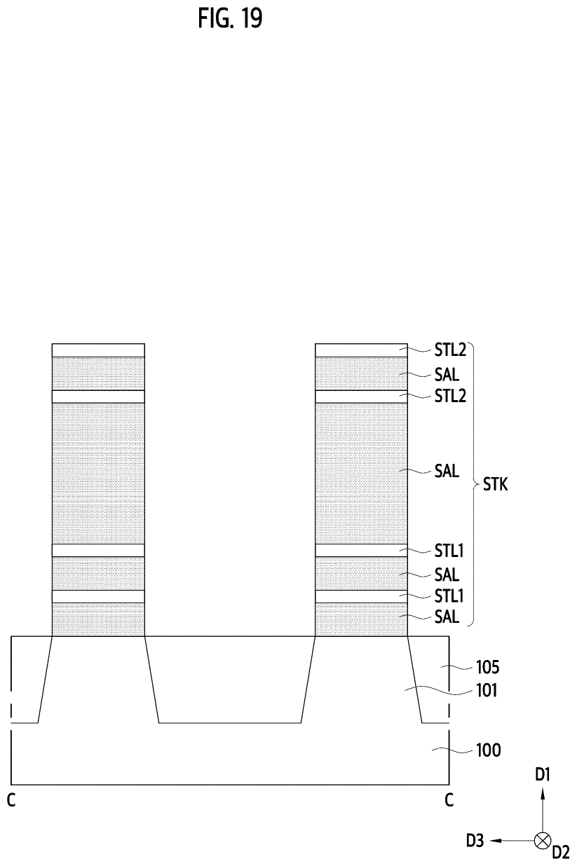

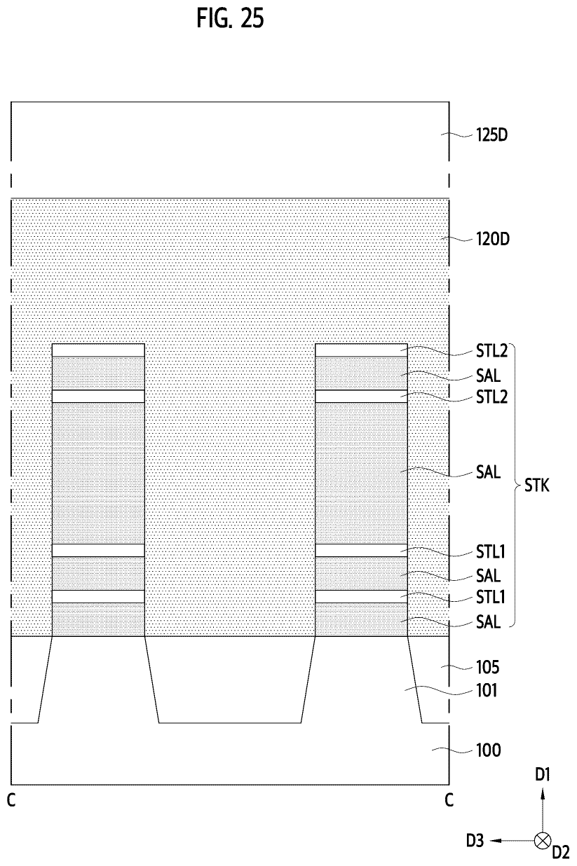

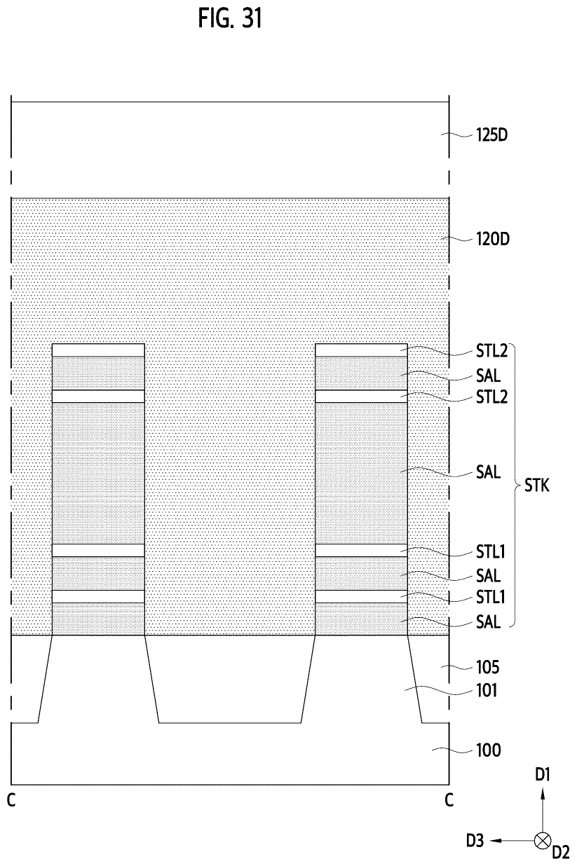

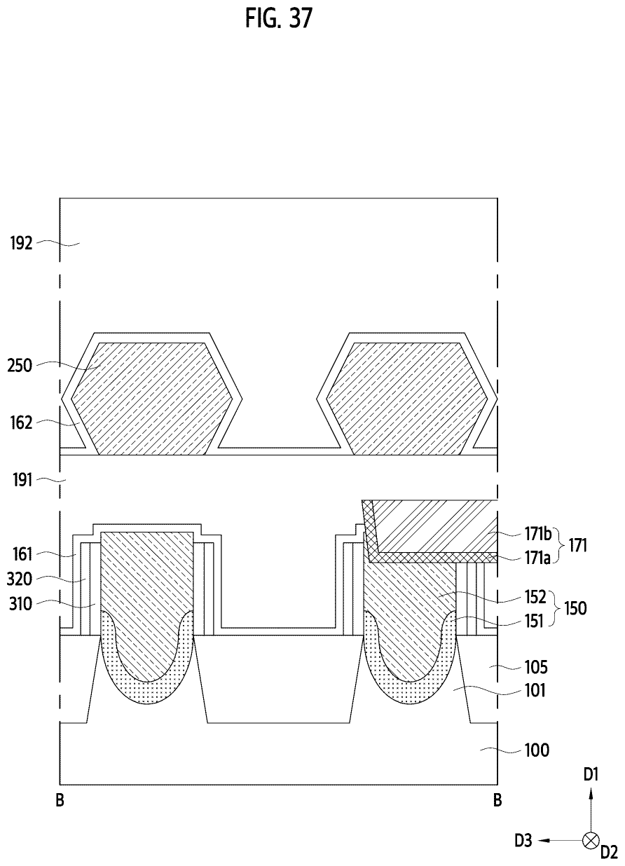

FIGS. 17 to 42 are schematic cross-sectional diagrams of intermediate stages for illustrating a manufacturing method of a semiconductor device according to some example embodiments. For reference, FIGS. 17 to 42 are schematic cross-sectional diagrams illustrating a semiconductor device in intermediate stages according to a manufacturing method of the semiconductor device illustrated in FIGS. 2 to 5.

Referring to FIGS. 17 to 19, a first sheet layer STL1 and a sacrificial layer SAL may be stacked alternately on the substrate 100 and the fin-type pattern 101 in the first direction D1, and a second sheet layer STL2 and the sacrificial layer SAL may be stacked alternately in the first direction D1.

Specifically, on the substrate 100 of the active region (AR of FIG. 1), a stacked structure STK in which the first sheet layer STL1, the sacrificial layer SAL, and the second sheet layer STL2 are stacked alternately in the first direction D1 may be formed. On the substrate 100 of the field region (FR of FIG. 1) where the field insulating film 105 is disposed, the stacked structure STK may not be formed. Accordingly, the upper surface of the field insulating film 105 may be exposed between the stacked structures STK. In other words, when viewed from the first direction D1, the stacked structures STK may be formed to extend in the second direction D2 and to be spaced apart in the third direction D3.

According to some example embodiments, the first sheet layer STL1 and the second sheet layer STL2 may include an identical material to each other and include different materials from the sacrificial layer SAL. For example, the first sheet layer STL1 and the second sheet layer STL2 may include silicon (Si) and the sacrificial layer SAL may include silicon-germanium (SiGe). However, example embodiments are not limited thereto. In addition, the first sheet layer STL1 and the second sheet layer STL2 may include identical materials to the substrate 100 and the fin-type pattern 101, but example embodiments are not limited thereto.

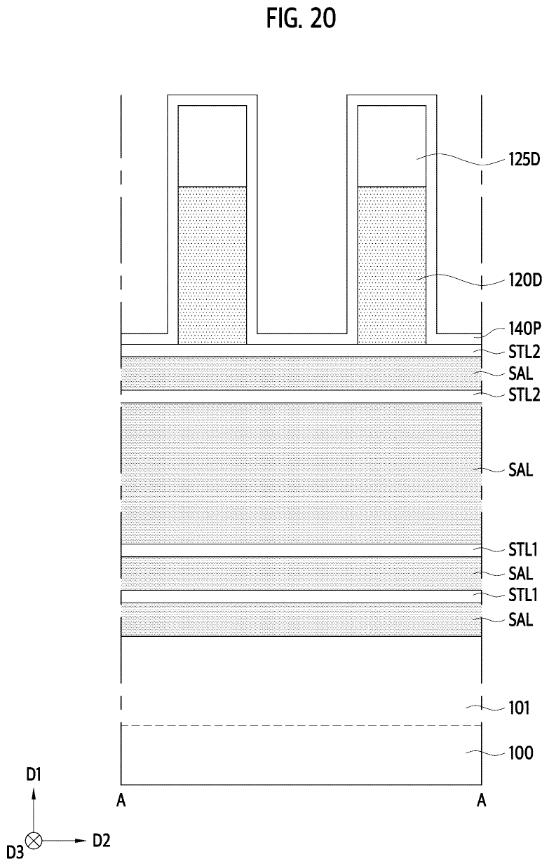

Further, referring to FIGS. 20 to 22, a dummy gate 120D, a dummy capping film 125D, and a pre-spacer 140P may be formed on the stacked structure STK.

According to some example embodiments, when viewed from the first direction D1, each of the dummy gates 120D and the dummy capping films 125D may be formed to extend in the third direction D3 and to be spaced apart in the second direction D2. The dummy gate 120D and the dummy capping film 125D may intersect the stacked structure STK.

According to some example embodiments, the pre-spacer 140P may be formed along profiles of the dummy gate 120D and the dummy capping film 125D, the upper surface of the field insulating film 105, and a profile of the stacked structure STK.

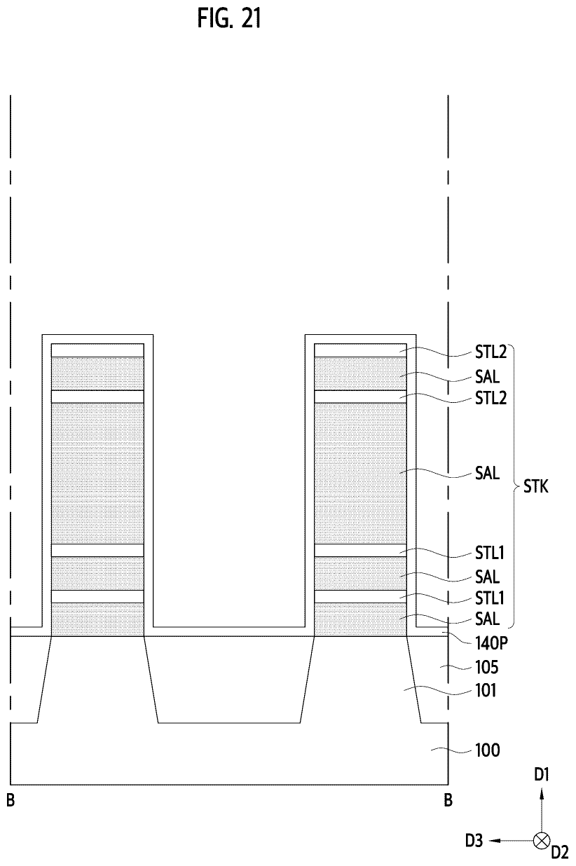

According to some example embodiments, the pre-spacer 140P may be formed on the stacked structure STK even in a region where the dummy gate 120D and the dummy capping film 125D are not formed. Accordingly, referring to FIG. 21, the pre-spacer 140P may be formed also on the stacked structure STK where the dummy gate 120D and the dummy capping film 125D are not intersected.

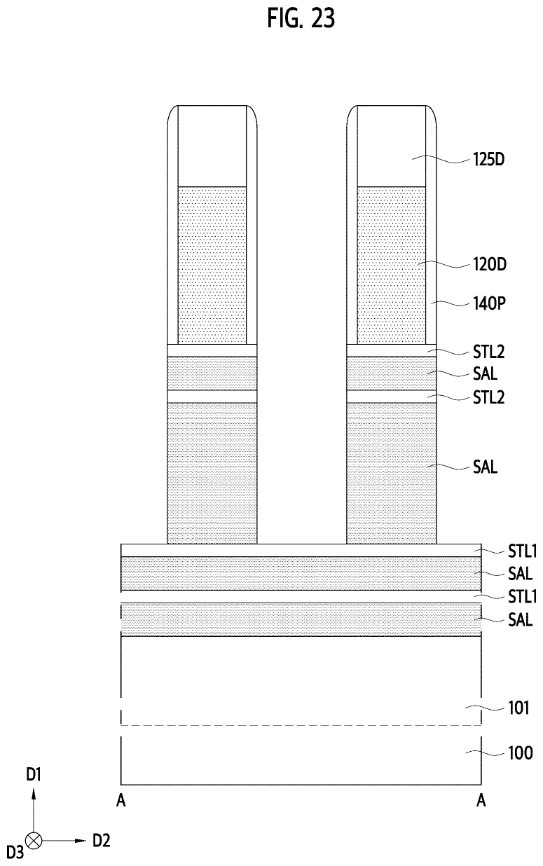

Further, referring to FIGS. 23 to 25, the second sheet layer STL2 and a portion of the sacrificial layer SAL may be patterned using the dummy gate 120D and the dummy capping film 125D as a mask.

Specifically, the second sheet layer STL2 and the sacrificial layer SAL disposed on the first sheet layer STL1 may be patterned so that the first sheet layer STL1 disposed uppermost in the first direction D1 is exposed. Since patterning is performed using the dummy gate 120D and the dummy capping film 125D as a mask, the second sheet layer STL2 and the sacrificial layer SAL not overlapping the dummy gate 120D and the dummy capping film 125D in the first direction D1 may be removed.

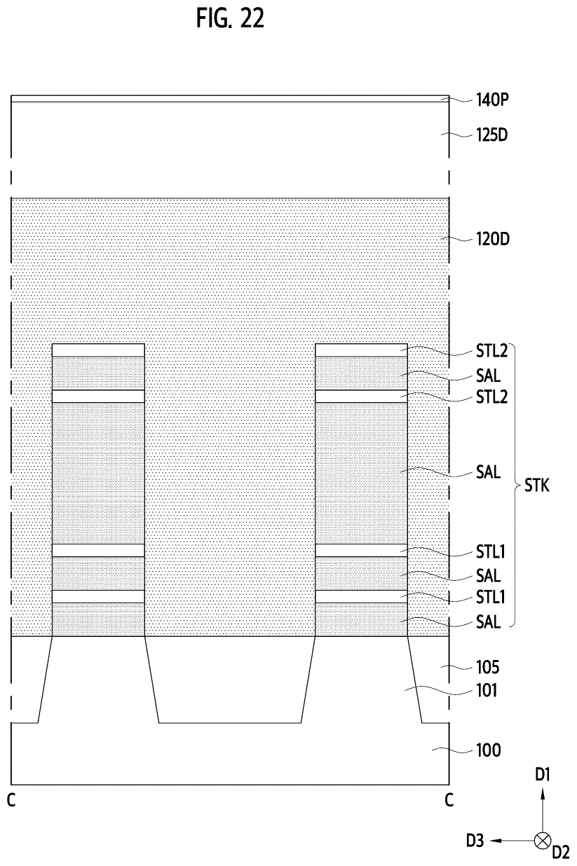

According to some example embodiments, while the second sheet layer STL2 and a portion of the sacrificial layer SAL are patterned, the pre-spacer (140P of FIG. 22) formed on the dummy gate 120D and the dummy capping film 125D may be removed.

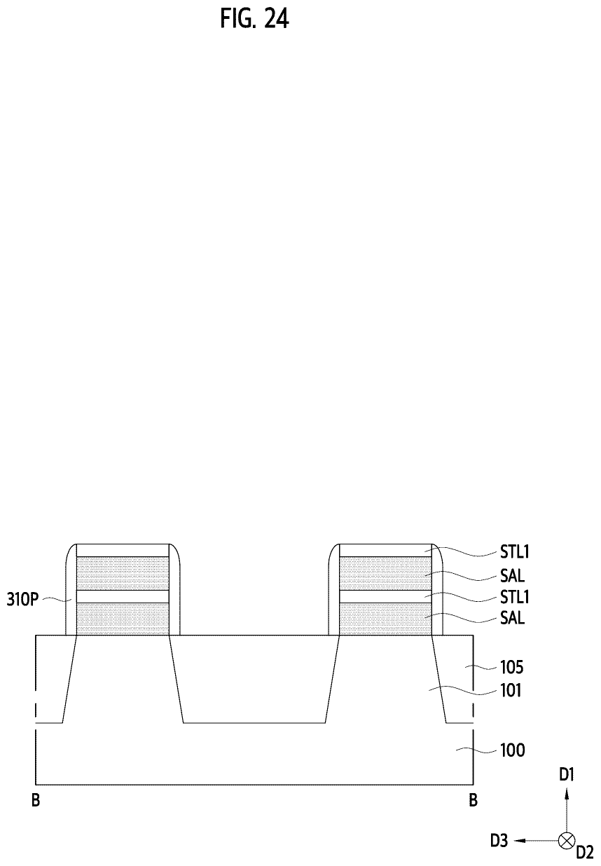

Referring to FIG. 24, in the third direction D3, a structure in which the sacrificial layer SAL and the first sheet layer STL1 are stacked alternately through the dummy gate 120D and the dummy capping film 125D may remain alone and the pre-spacer (140P of FIG. 21) formed on the field insulating film 105 may be removed. As the pre-spacer (140P of FIG. 21) is patterned on a side surface of the structure in which the sacrificial layer SAL and the first sheet layer STL1 are stacked alternately, a first pre-fence film 310P may be formed. In other words, as a portion where the second sheet layer (STL2 of FIG. 21) and the sacrificial layer SAL are stacked alternately is patterned, a portion of the pre-spacer (140P of FIG. 21) formed on a side surface of the stacked structure (STK of FIG. 21) may be removed. After the portion of the pre-spacer (140P of FIG. 21) formed on the side surface of the stacked structure (STK of FIG. 21) is removed, the remaining pre-spacer (140P of FIG. 21) may be the first pre-fence film 310P formed on the side surface of the structure in which the sacrificial layer SAL and the first sheet layer STL1 are stacked alternately in the first direction D1. Therefore, the first pre-fence film 310P and the pre-spacer (140P of FIG. 21) may include an identical material.

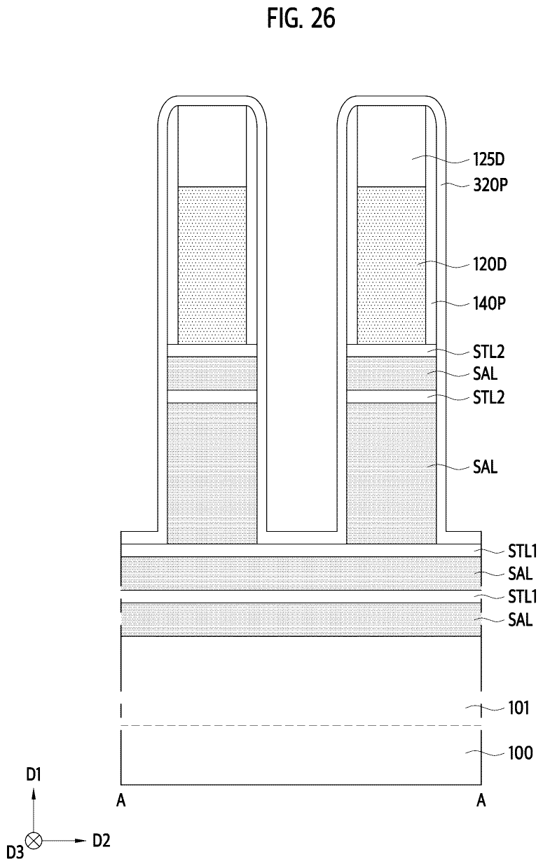

Further, referring to FIGS. 26 to 28, a second pre-fence film 320P may be formed.

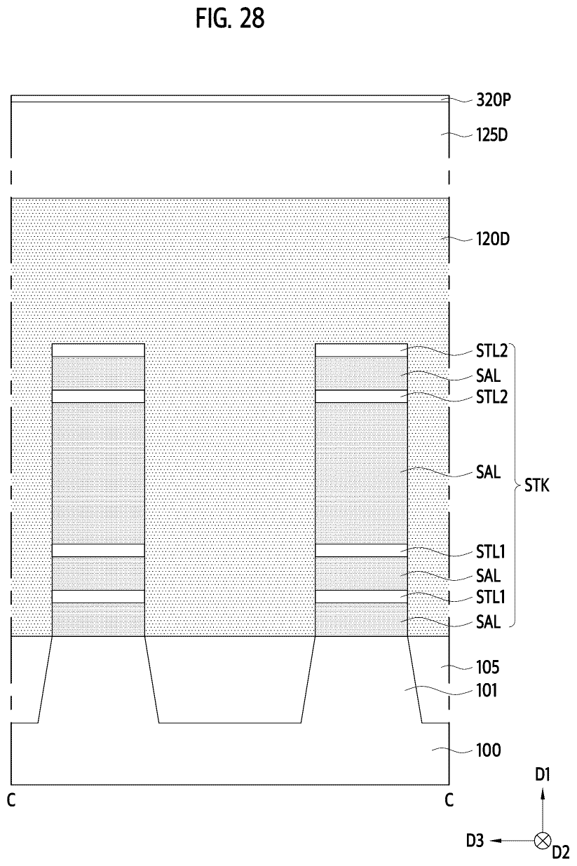

Specifically, referring to FIGS. 26 and 28, on the substrate 100 of the active region (AR of FIG. 1), the second pre-fence film 320P may extend along profiles of the dummy gate 120D, the dummy capping film 125D, the pre-spacer 140P, a side surface of the stacked second sheet layer STL2 and sacrificial layer SAL, and an upper surface of the exposed first sheet layer STL1. The second pre-fence film 320P may be formed on the dummy capping film 125D that is exposed as the pre-spacer (140P of FIG. 22) is removed.

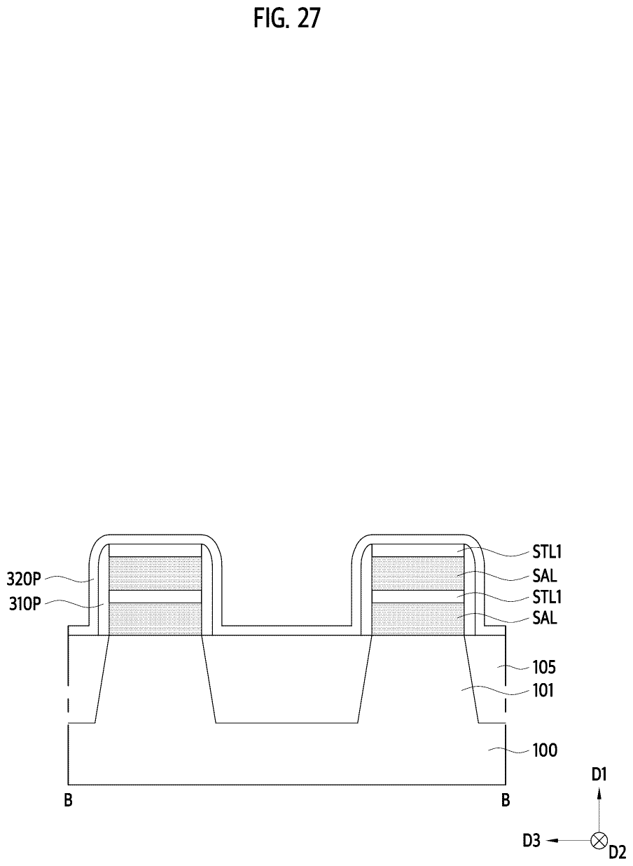

Specifically, referring to FIG. 27, the second pre-fence film 320P may be formed along profiles of the structure in which the sacrificial layer SAL and the first sheet layer STL1 are stacked alternately in the first direction D1 and the first pre-fence film 310P. The second pre-fence film 320P may be formed along an outer sidewall of the first pre-fence film 310P, the upper surface of the first sheet layer STL1, and the upper surface of the field insulating film 105.

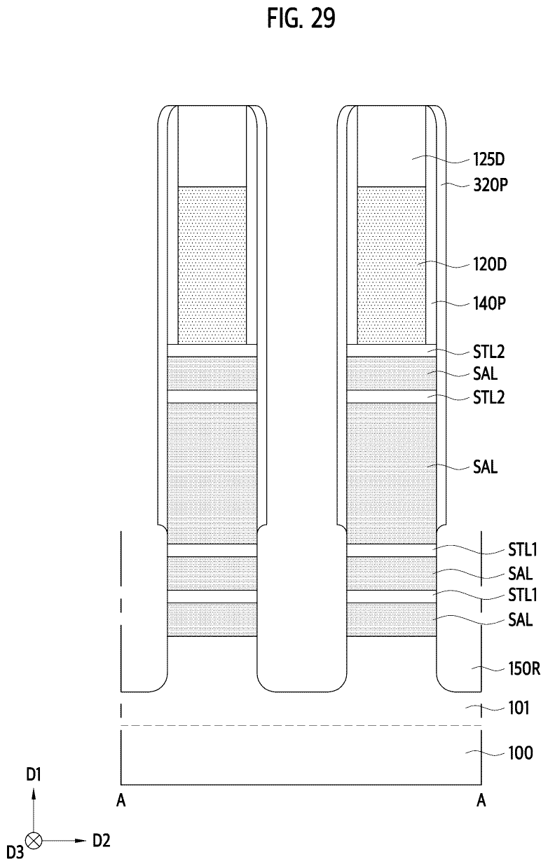

Further, referring to FIGS. 29 to 31, a portion where the first sheet layer STL1 and the sacrificial layer SAL are stacked alternately in the first direction D1 may be patterned using the dummy gate 120D and the dummy capping film 125D as a mask in a manner consistent with the patterning of the second sheet layer STL2 and a portion of the sacrificial layer SAL (see FIG. 23).

According to some example embodiments, as the first sheet layer STL1 and the sacrificial layer SAL, not overlapping the dummy gate 120D and the dummy capping film 125D, are removed, the recess 150R of the first source/drain pattern may be formed. In the second direction D2, sidewalls of the first sheet layer STL1 may be exposed through the recess 150R of the first source/drain pattern. As the second pre-fence film (320P of FIG. 28) disposed on an upper surface of the dummy capping film 125D is removed when the recess 150R of the first source/drain pattern is formed, the upper surface of the dummy capping film 125D may be exposed.

According to some example embodiments, while the recess 150R of the first source/drain pattern is formed as the first sheet layer (STL1 of FIG. 27) and the sacrificial layer (SAL of FIG. 27) which are disposed between the first pre-fence films (310P of FIG. 27) and the second pre-fence films (320P of FIG. 27) in the third direction D3 are removed, portions of the first pre-fence film (310P of FIG. 27) and the second pre-fence film (320P of FIG. 27) may also be removed. Therefore, when the recess 150R of the first source/drain pattern is formed, the first fence film 310 may be formed. The recess 150R of the first source/drain pattern may be disposed between the first fence films 310 and the second pre-fence films 320P on the fin-type pattern 101.

According to some example embodiments, the protrusion part 101P may be formed on the fin-type pattern 101 while the recess 150R of the first source/drain pattern is indented convexly toward the substrate 100. Since the fin-type pattern 101 has a width between the field insulating films 105 in the third direction D3 greater than a width between the dummy gates 120D in the second direction D2, the protrusion part 101P may be represented on a cross-section including the first direction D1 and the third direction D3.

Specifically, on a cross-section including the first direction D1 and the second direction D2, since a width of a portion in which the recess 150R of the first source/drain pattern is formed in the fin-type pattern 101 is relatively small, the recess 150R of the first source/drain pattern may be formed deeply up to an edge area of the fin-type pattern 101. In contrast, since a width of the fin-type pattern 101 between the first fence films 310 in the third direction D3 is relatively large, the recess 150R of the first source/drain pattern may not be formed deeply up to the edge area of the fin-type pattern 101, and the recess 150R of the first source/drain pattern may be formed by a gentle inclination in the edge area. Accordingly, the protrusion part 101P may be formed between the recess 150R of the first source/drain pattern and the field insulating film 105 in the third direction D3.

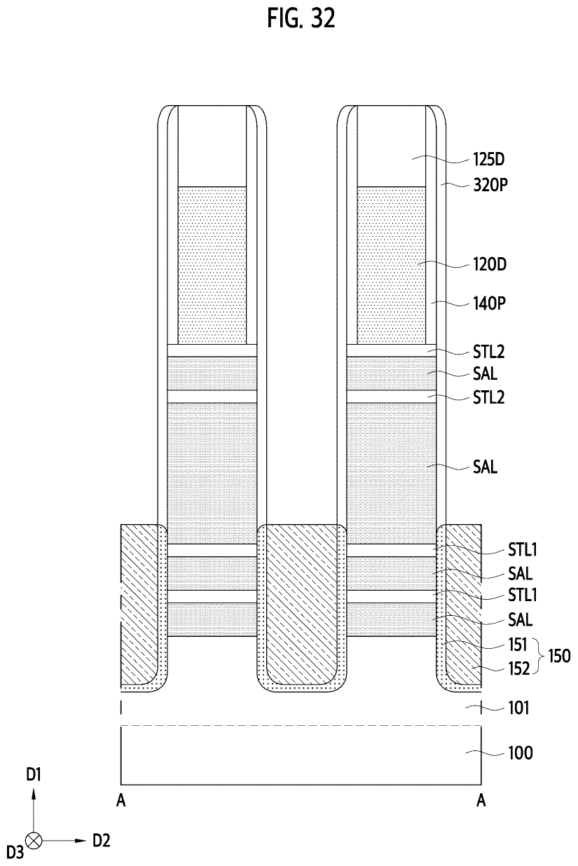

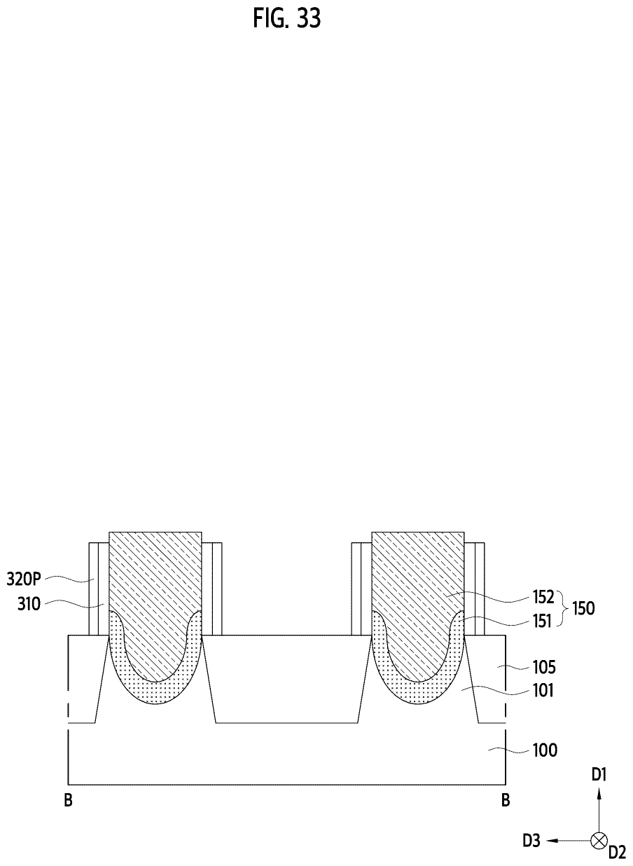

Further, referring to FIGS. 32 and 33, the first source/drain pattern 150 may be formed.

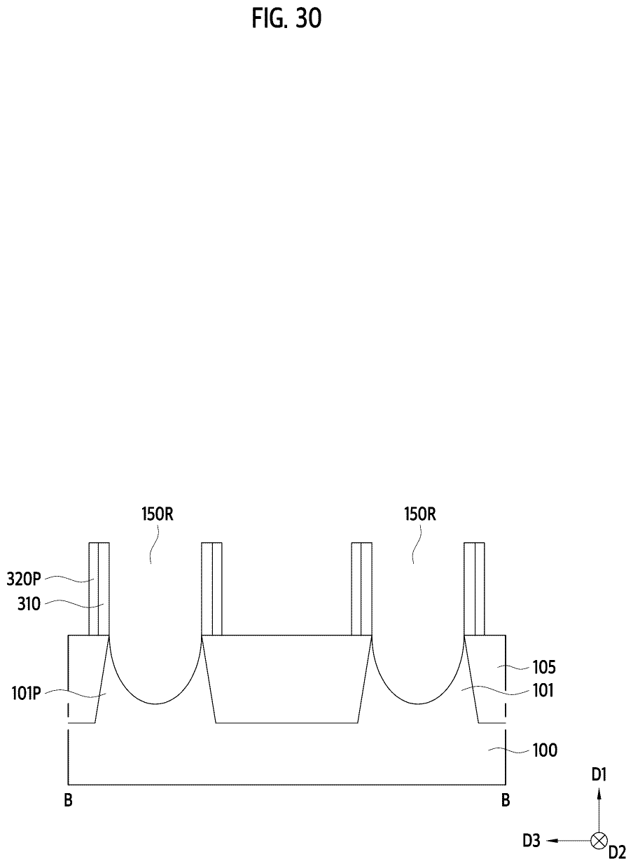

Specifically, the first film 151 and the second film 152 may be formed within the recess (150R of FIGS. 29 and 30) of the first source/drain pattern 150. The first film 151 and the second film 152 may be formed through epitaxial growth of a semiconductor material. For example, the first film 151 and the second film 152 may include silicon germanium. The first film 151 may be formed along a surface of the recess (150R of FIGS. 29 and 30) of the first source/drain pattern formed to be U-shaped on the fin-type pattern 101. Accordingly, the first film 151 may also be formed to be U-shaped.

According to some example embodiments, since the first source/drain pattern 150 is formed between the first fence films 310 and the second pre-fence films 320P in the third direction D3, a width of the first source/drain pattern 150 in the third direction D3 may be formed up to a maximum distance between the first fence films 310.

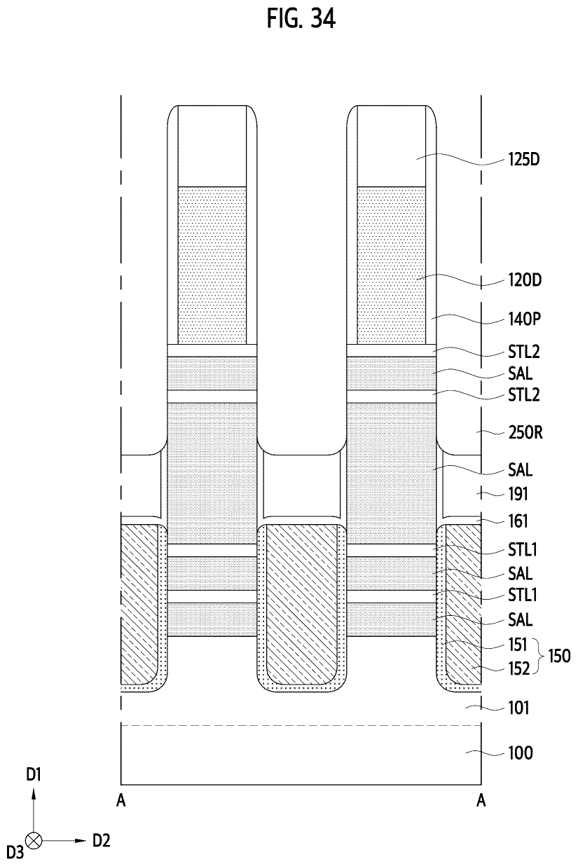

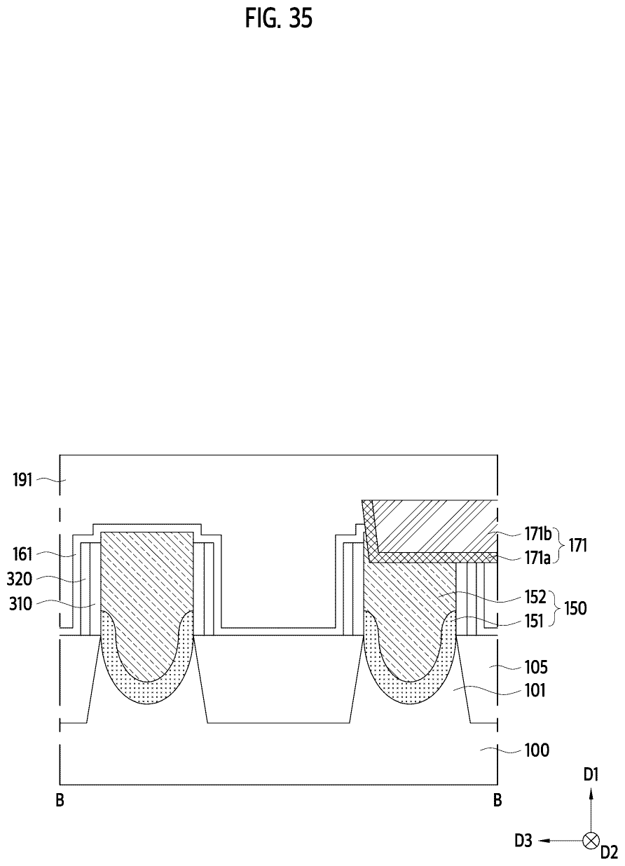

Further, referring to FIGS. 34 and 35, the first source/drain etch stop film 161 and the first interlayer insulating film 191 may be formed on the first source/drain pattern 150. In addition, the first source/drain contact 171 electrically connected to the first source/drain pattern 150 may be formed within the first interlayer insulating film 191. On the first interlayer insulating film 191, a recess 250R of the second source/drain pattern where the second sheet layer STL2 is exposed may be formed.

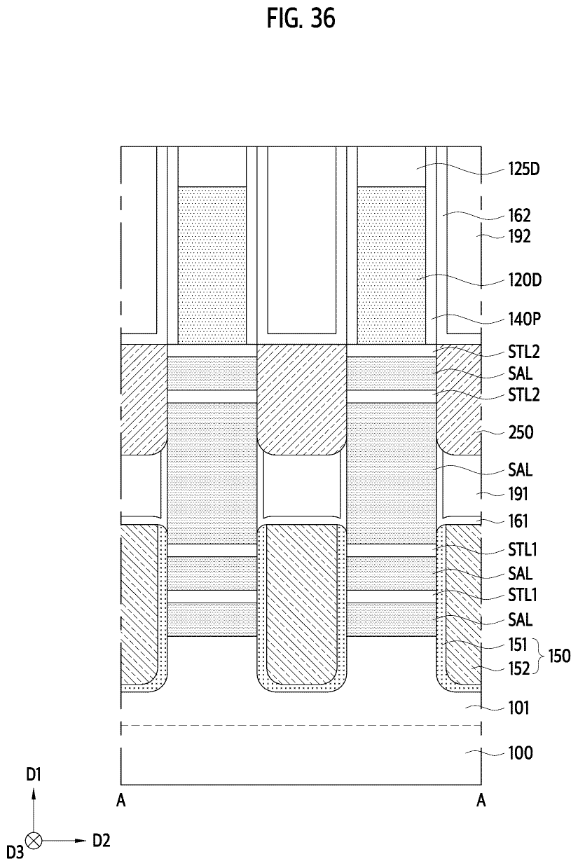

Further, referring to FIGS. 36 to 38, the second source/drain pattern 250, the second source/drain etch stop film 162, and the second interlayer insulating film 192 may be formed.

According to some example embodiments, the second source/drain pattern 250 may fill the recess (250R of FIG. 34) of the second source/drain pattern.

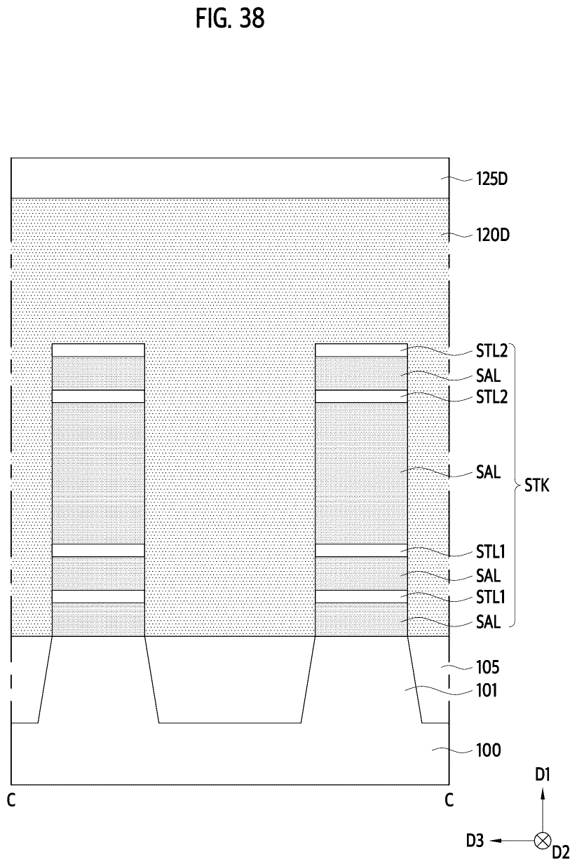

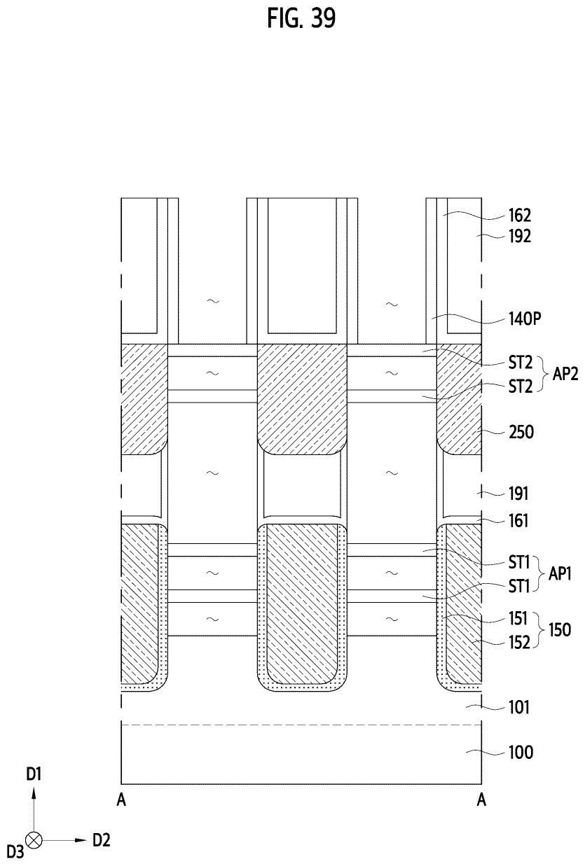

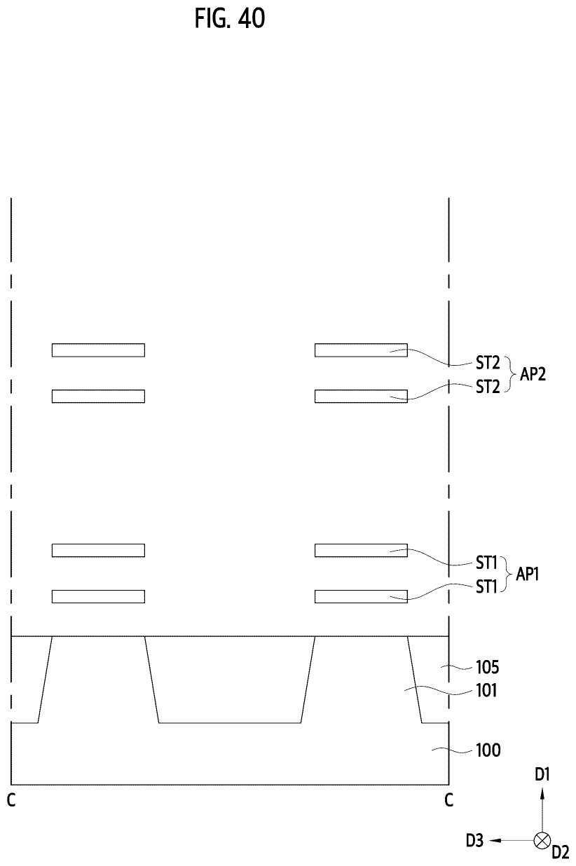

Further, referring to FIGS. 39 and 40, the dummy gate (120D of FIGS. 36 and 38) and the dummy capping film (125D of FIGS. 36 and 38) may be removed, and the first sheets ST1 and the second sheets ST2 may be formed.

Specifically, while the sacrificial layer (SAL of FIGS. 36 and 38) is removed and the sheet layers STL1 and STL2 are exposed, the first sheets ST1 and the second sheets ST2 may be formed. An upper surface and a lower surface of each of the first sheets ST1 connected to the first source/drain pattern 150 may be exposed. An upper surface and a lower surface of each of the second sheets ST2 connected to the second source/drain pattern 250 may be exposed.

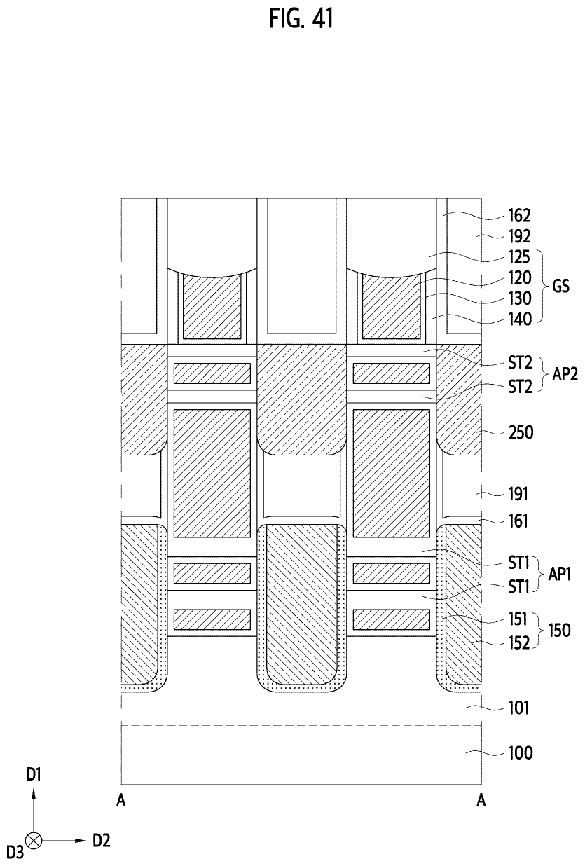

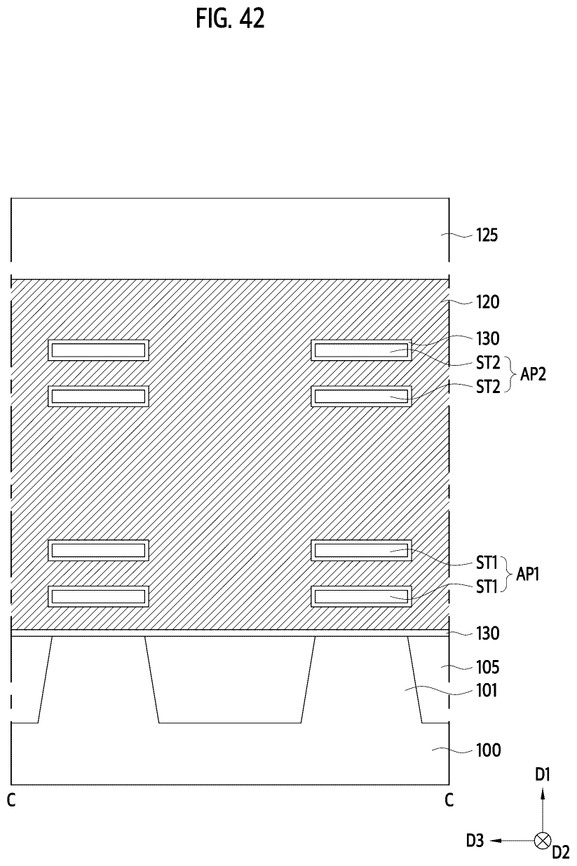

Further, referring to FIGS. 41 and 42, the gate insulating film 130, the gate electrode 120, and the gate capping film 125 may be formed.

Specifically, the gate insulating film 130 and the gate electrode 120 may be formed along surfaces of the first sheets ST1 and the second sheets ST2.

Further, referring to FIGS. 2 to 5, the first etch stop film 196, the third interlayer insulating film 193, the second etch stop film 197, and the fourth interlayer insulating film 194 may be formed, and the gate contact 180 electrically connected to the gate electrode 120 may be formed.

While various example embodiments of the present disclosure are described in detail above, the scope of the present disclosure is not limited thereto, and it will be apparent to those of ordinary skill in the art that modifications and variations may be made without departing from the scope of the present disclosure as defined by the appended claims. In addition, the aforementioned example embodiments may be implemented with some elements removed, and each example embodiment may be implemented in combination with each other.

What is claimed is:

1. A semiconductor device, comprising:
a first active pattern including a plurality of first sheets spaced apart from one another in a first direction perpendicular to a surface of a substrate;
a second active pattern on the first active pattern and including a plurality of second sheets spaced apart from one another in the first direction;
a first source/drain pattern connected to the first active pattern in a second direction intersecting the first direction;
a second source/drain pattern on the first source/drain pattern and connected to the second active pattern in the second direction; and
a gate electrode extending in a third direction intersecting the first direction and the second direction and extending around the first active pattern and the second active pattern,
wherein the first source/drain pattern includes:
a first film formed along an inner surface of a recess in which the first source/drain pattern is disposed; and
a second film on the first film and at least partially filling the recess, and
wherein, on a cross-section including the first direction and the third direction, the recess decreases in width in the third direction as the recess extends closer to the substrate in the first direction.

2. The semiconductor device of claim 1, further comprising:
a first fence film on a sidewall of the first source/drain pattern in the third direction; and
a second fence film on the first fence film in the third direction.

3. The semiconductor device of claim 2, further comprising a gate spacer on a sidewall of the gate electrode in the second direction,
wherein the gate spacer and the first fence film include an identical material.

4. The semiconductor device of claim 2, further comprising a fin-type pattern extending from the substrate in the first direction, below the first active pattern, and extending longitudinally in the second direction,
wherein the first source/drain pattern is on the fin-type pattern, and
wherein the fin-type pattern includes a protrusion part on the sidewall of the first source/drain pattern in the third direction.

5. The semiconductor device of claim 4, wherein the protrusion part decreases in width in the third direction as the protrusion part extends farther from the substrate in the first direction.

6. The semiconductor device of claim 2, wherein, in the first direction, an upper surface of the first source/drain pattern is at or above a level of an upper surface of the first fence film and an upper surface of the second fence film, with respect to the surface of the substrate.

7. The semiconductor device of claim 2, wherein the second film of the first source/drain pattern includes:
a first portion of which at least a portion overlaps the first fence film and the second fence film in the third direction; and
a second portion extending from the first portion toward the second source/drain pattern and being non-overlapping with respect to the first fence film and the second fence film in the third direction, and
wherein, in the third direction, a width of the second portion is greater than a width of the first portion.

8. The semiconductor device of claim 1, wherein, on a cross-section including the first direction and the third direction, at least a portion of the first source/drain pattern increases in width in the third direction as the first source/drain pattern extends farther from the substrate in the first direction.

9. The semiconductor device of claim 1, wherein the first source/drain pattern and the second source/drain pattern have different conductivity types.

10. The semiconductor device of claim 1, further comprising a supporter below the first source/drain pattern in the first direction.

11. The semiconductor device of claim 10, wherein, in the first direction, an upper surface of the supporter and a lower surface of the supporter curve toward an upper surface of the substrate, and
wherein the upper surface of the supporter has a radius of curvature that is less than a radius of curvature of the lower surface of the supporter.

12. The semiconductor device of claim 1, wherein, in the third direction, a width of the first source/drain pattern is less than a width of the second source/drain pattern.

13. The semiconductor device of claim 1, wherein, in the first direction, a height of the first source/drain pattern is greater than a height of the second source/drain pattern, relative to the surface of the substrate.

14. The semiconductor device of claim 1, wherein the second film includes:
a first epitaxial film, the first film extending around a side surface of the first epitaxial film on a cross-section including the first direction and the third direction; and
a second epitaxial film on the first epitaxial film and the first film on a cross-section including the first direction and the third direction.

15. A semiconductor device, comprising:
a first active pattern including a plurality of first sheets spaced apart from one another in a first direction perpendicular to a surface of a substrate;
a second active pattern on the first active pattern and including a plurality of second sheets spaced apart from one another in the first direction;
a first source/drain pattern connected to the first active pattern in a second direction intersecting the first direction;
a second source/drain pattern on the first source/drain pattern and connected to the second active pattern in the second direction;
a gate electrode extending in a third direction intersecting the first direction and the second direction and extending around the first active pattern and the second active pattern;
a first fence film on a sidewall of the first source/drain pattern in the third direction; and
a second fence film on the first fence film in the third direction.

16. The semiconductor device of claim 15, wherein the first source/drain pattern includes:
a first film along an inner surface of a recess in which the first source/drain pattern is disposed, the first film is U-shaped; and
a second film on the first film and at least partially filling the recess.

17. The semiconductor device of claim 15, wherein, in the third direction, a width of the first source/drain pattern is less than a width of the second source/drain pattern.

18. The semiconductor device of claim 15, further comprising a first source/drain pattern etch stop film extending along an upper surface of the first source/drain pattern, an upper surface of the first fence film, and an upper surface of the second fence film.

19. The semiconductor device of claim 15, wherein the substrate includes:
an active region including the first active pattern and the second active pattern; and
a field region alternating with the active region in the third direction,
wherein the field region includes a field insulating film on the substrate, and
wherein the first fence film and the second fence film at least partially overlap the field insulating film in the first direction.

20. A semiconductor device, comprising:
a first active pattern including a plurality of first sheets spaced apart from one another in a first direction perpendicular to a surface of a substrate;
a second active pattern on the first active pattern and including a plurality of second sheets spaced apart from one another in the first direction;
a first source/drain pattern connected to the first active pattern in a second direction intersecting the first direction;
a second source/drain pattern on the first source/drain pattern and connected to the second active pattern in the second direction;
a fin-type pattern extending from the substrate in the first direction, extending longitudinally in the second direction, and below the first active pattern;
a gate electrode extending in a third direction intersecting the first direction and the second direction and extending around the first active pattern and the second active pattern;
a first fence film on a sidewall of the first source/drain pattern in the third direction; and
a second fence film on the first fence film in the third direction,
wherein the fin-type pattern includes a protrusion part between the first source/drain pattern and the first fence film in the third direction,
wherein the first source/drain pattern includes:
a first film along an inner surface of a recess in which the first source/drain pattern is disposed; and
a second film on the first film and at least partially filling the recess,
wherein the first source/drain pattern has a p-type conductivity, and
wherein the second source/drain pattern has an n-type conductivity.
